(19) United States
(12) Patent Application Publication
(10) Pub. No.: US 2026/0357109 A1
(43) Pub. Date: Nov. 12, 2026

(54) POLISHING SLURRY AND METHOD OF MANUFACTURING SEMICONDUCTOR DEVICE

(71) Applicant: SAMSUNG ELECTRONICS CO., LTD., Suwon-si (KR)

(72) Inventors: Fedosya KALININA, Suwon-si (KR); Sang Soo JEE, Suwon-si (KR); Yoonseok KO, Suwon-si (KR); YOUNHWA KANG, Suwon-si (KR); Juhyung LIM, Suwon-si (KR); Hyune Jea LEE, Suwon-si (KR)

(21) Appl. No.: 19/629,705

(22) Filed: Mar. 26, 2026

(30) Foreign Application Priority Data
Apr. 29, 2025 (KR) 10-2025-0056483

(51) Int. Cl. C09G 1/02; B24B 37/04; H10P 52/40

(52) U.S. Cl. CPC C09G 1/02; B24B 37/044; H10P 52/403

(57) ABSTRACT

The present disclosure relates to a polishing slurry including an abrasive, an oxidizing agent, and a polymerization product of at least one histidine derivative including a substituted or unsubstituted cyclic imide group, a substituted or unsubstituted amic acid group, or a combination thereof, and a method of manufacturing a semiconductor device including the polishing slurry.

### CROSS-REFERENCE TO RELATED APPLICATION

This U.S. nonprovisional patent application claims the benefit of and priority to Korean Patent Application No. 10-2025-0056483 filed in the Korean Intellectual Property Office on Apr. 29, 2025, and all the benefits accruing therefrom under 35 U.S.C § 119, the content of which in its entirety is incorporated herein by reference.

### BACKGROUND

### 1. Field

The present disclosure relates to a polishing slurry and a method of manufacturing a semiconductor device.

### 2. Description of the Related Art

Recently, due to the miniaturization of electronic devices and the subsequent miniaturization of integrated circuits, various methods of forming microstructures such as metal wires with a width of several nanometers, contact holes, or shallow trench isolations have been studied.

In forming such microstructures, polishing processes may be performed to make the surface of the microstructures flat and smooth, and chemical mechanical polishing (CMP) may be one of the polishing processes. Chemical mechanical polishing is a process of polishing an object to be polished by providing a polishing slurry.

### SUMMARY

While chemical mechanical polishing may effectively polish an object to be polished, such as a metal, loss or defects may occur in the object to be polished due to corrosion or over-etching by the polishing slurry.

An embodiment provides a polishing slurry capable of reducing or preventing loss or defects in an object to be polished during a chemical mechanical polishing process.

An embodiment provides a method of manufacturing a semiconductor device using the polishing slurry.

According to an embodiment, a polishing slurry includes an abrasive, an oxidizing agent, and a polymerization product of one or more histidine derivatives, the one or more histidine derivatives including a substituted or unsubstituted cyclic imide group, a substituted or unsubstituted amic acid group, or a combination thereof.

The polymerization product of the one or more histidine derivatives may include a polymerization product of a first histidine derivative including a substituted or unsubstituted cyclic imide group, a polymerization product of a second histidine derivative including a substituted or unsubstituted amic acid group, a copolymerization product of the first histidine derivative and the second histidine derivative, or a combination thereof.

The first histidine derivative may be represented by Chemical Formula 1-1, and the second histidine derivative may be represented by Chemical Formula 1-2:

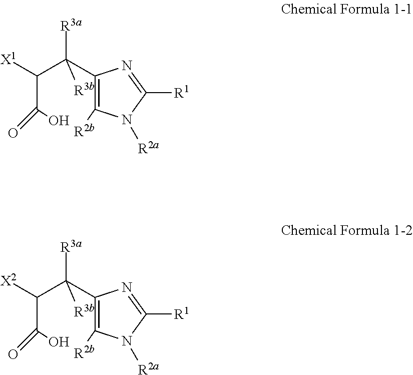

where in Chemical Formula 1-1 or 1-2,
X¹ may be a substituted or unsubstituted cyclic imide group having a polymerizable unsaturated bond,
X² may be a substituted or unsubstituted amic acid group having a polymerizable unsaturated bond,
R¹, R^{2a}, R^{2b}, R^{3a}, and R^{3b} may each independently be hydrogen, deuterium, a substituted or unsubstituted C1 to C20 alkyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} may each independently be present or any two adjacent R¹, R^{2a}, R^{2b}, R^{3a}, and R^{3b} may be linked to form a ring.
X¹ of Chemical Formula 1-1 may be represented by any one of Chemical Formulae A to D:

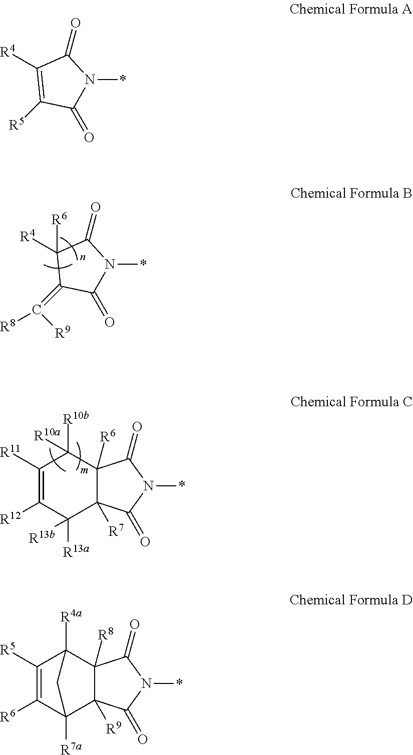

where in Chemical Formulae A to D,
R⁴, R^{4a}, R⁵, R⁶, R⁷, R^{7a}, R⁸, R⁹, R^{10a}, R^{10b}, R¹¹, R¹², R^{13a}, and R^{13b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴, R^{4a}, R⁵, R⁶, R⁷, R^{7a}, R⁸, R⁹, R^{10a}, R^{10b}, R¹¹, R¹², R^{13a}, and R^{13b} may each independently be present or any two adjacent R⁴, R^{4a}, R⁵, R⁶, R⁷, R^{7a}, R⁸, R⁹, R^{10a}, R^{10b}, R¹¹, R¹², R^{13a}, and R^{13b} may be linked to form a ring,
n may be an integer of 1 to 5,
m may be an integer of 0 to 5, and
* may be a linking point with Chemical Formula 1-1.

X² of Chemical Formula 1-2 may be represented by any one of Chemical Formulae E to H:

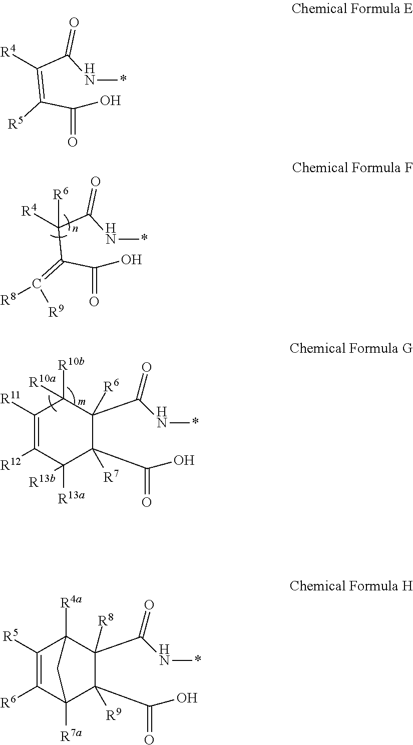

wherein Chemical Formulae E to H,
R⁴, R^{4a}, R⁵, R⁶, R⁷, R^{7a}, R⁸, R⁹, R^{10a}, R^{10b}, R¹¹, R¹², R^{13a}, and R^{13b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴, R^{4a}, R⁵, R⁶, R⁷, R^{7a}, R⁸, R⁹, R^{10a}, R^{10b}, R¹¹, R¹², R^{13a}, and R^{13b} may each independently be present or any two adjacent R⁴, R^{4a}, R⁵, R⁶, R⁷, R^{7a}, R⁸, R⁹, R^{10a}, R^{10b}, R¹¹, R¹², R^{13a}, and R^{13b} may be linked to form a ring,
n may be an integer of 1 to 5,
m may be an integer of 0 to 5, and
* may be a linking point with Chemical Formula 1-2.

At least some repeating units of the polymerization product of the first histidine derivative may include a substituted or unsubstituted cyclic imide moiety, a substituted or unsubstituted imidazole moiety, and a carboxyl moiety, and at least some repeating units of the polymerization product of the second histidine derivative may include at least one of a substituted or unsubstituted amic acid moiety or a substituted or unsubstituted cyclic imide moiety, a substituted or unsubstituted imidazole moiety, and a carboxyl moiety.

The polymerization product of the histidine derivative may include one or more repeating units represented by any one of Chemical Formulae 2-1 to 2-10:

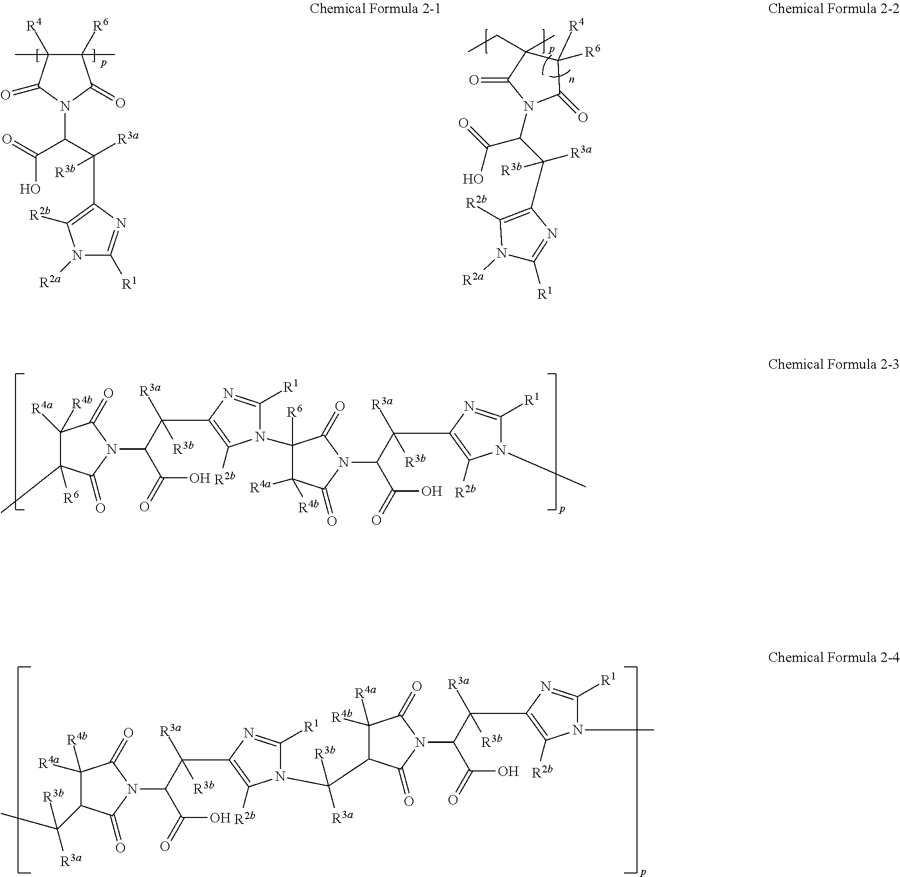

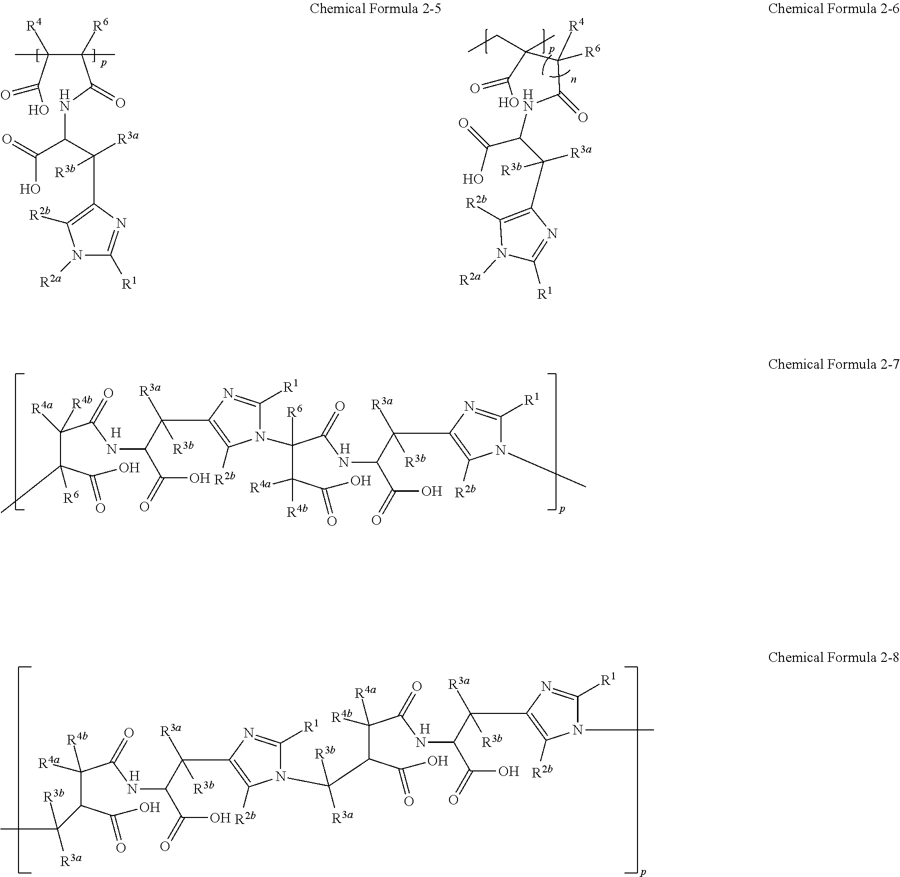

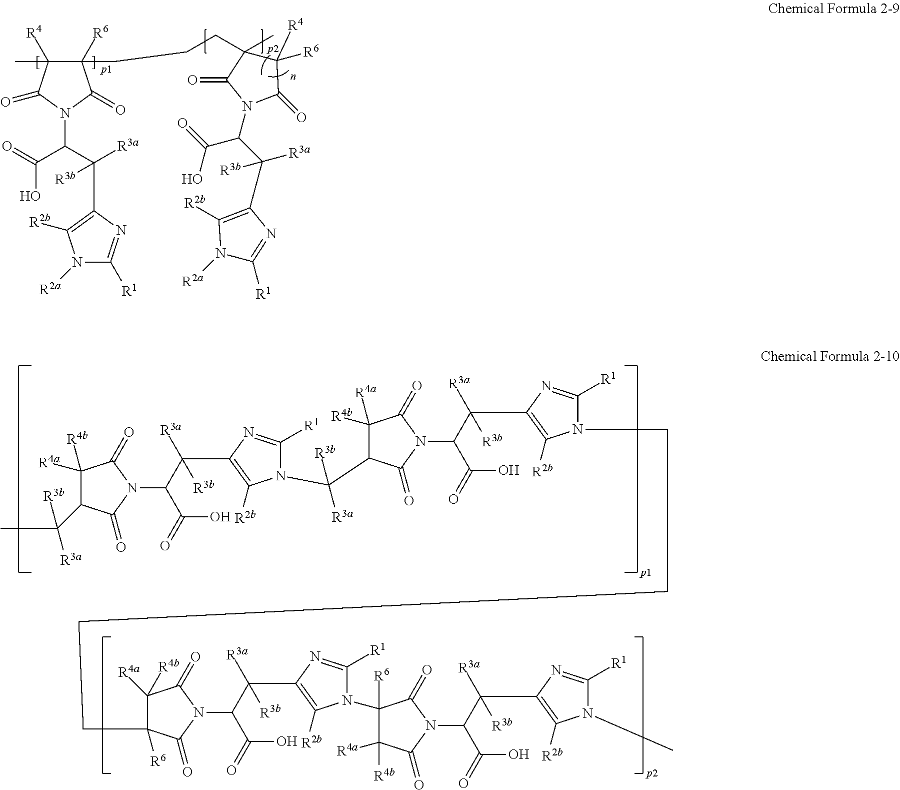

where in Chemical Formulae 2-1 to 2-10,
R¹, R^{2a}, R^{2b}, R^{3a}, R^{3b}, R⁴, R^{4a}, R^{4b}, and R⁶ may each independently be hydrogen, deuterium, a substituted or unsubstituted C1 to C20 alkyl group, a substituted or unsubstituted C1 to C20 alkoxy group, a substituted or unsubstituted C6 to C20 aryl group, a carboxyl group, a hydroxy group, a halogen, or a cyano group,
n may be an integer of 1 to 5, and
p, p1, and p2 may each independently be an integer of 2 to 100.

The polishing slurry may further include a first histidine derivative having a substituted or unsubstituted cyclic imide group, a second histidine derivative having a substituted or unsubstituted amic acid group, or a combination thereof.

The abrasive may include an oxide abrasive, a nitride abrasive, a carbon abrasive, or a combination thereof.

The abrasive may include silica (SiO₂), ceria (CeO₂), alumina (Al₂O₃), zirconia (ZrO₂), titania (TiO₂), silicon nitride (SiN), silicon carbide (SiC), diamond, fullerene, a derivative thereof, or a combination thereof.

The oxidizing agent may include hydrogen peroxide, peracetic acid, a percarbonate (e.g., sodium or potassium), urea peroxide, perchloric acid, a persulfate (e.g., sodium, potassium, or ammonium), or a combination thereof.

The polishing slurry may further include a dispersion medium, and the polymerization product of the one or more histidine derivative and the oxidizing agent may each be included in an amount of about 0.001 weight percent (wt %) to about 5 wt % based on a total weight of the polishing slurry, and the polymerization product of the one or more histidine derivative and the oxidizing agent may be included in a molar ratio of about 0.01:10 to about 10:0.01 in the polishing slurry.

The pH of the polishing slurry may be about 1.0 to about 10.0.

According to an embodiment, a method of manufacturing a semiconductor device includes: forming a conductive layer on a dielectric layer having a trench or a hole; supplying a polishing slurry on the conductive layer; and performing chemical mechanical polishing on the conductive layer to form a conductive pattern embedded in the trench or the hole, wherein the polishing slurry includes an abrasive, an oxidizing agent, and a polymerization product of one or more histidine derivatives including a substituted or unsubstituted cyclic imide group, a substituted or unsubstituted amic acid group, or a combination thereof.

The conductive layer may include a molybdenum-containing conductive layer, and a ratio of a removal rate to a static etching rate of the molybdenum-containing conductive layer may be greater than or equal to about 30, wherein the removal rate is determined according to Calculation Equation 1 and the static etching rate is determined according to Calculation Equation 3

Removal rate (RR, Å/min)=(thickness of Mo layer before polishing (Å)−thickness of Mo layer after polishing (Å))/polishing time (min) Calculation Equation 1

Static etching rate (SER, Å/min)=(thickness of Mo layer before immersion (Å)−thickness of Mo layer after immersion (Å))/immersion time (min). Calculation Equation 3

Loss or defects in an object to be polished may be effectively reduced or prevented during a chemical mechanical polishing process.

### BRIEF DESCRIPTION OF THE DRAWINGS

The above and other objects, features, and advantages of the present disclosure are more apparent to those of ordinary skill in the art by describing example embodiments thereof in detail with reference to the accompanying drawings, in which:

FIGS. 1 to 4 are cross-sectional views showing an example of a method of manufacturing a semiconductor device according to an embodiment,

FIG. 5 is a schematic view showing chemical mechanical polishing equipment according to an example, and

FIG. 6 is a conceptual view showing an example of an electronic device according to an embodiment.

### DETAILED DESCRIPTION

Example embodiments will hereinafter be described in detail, and may be easily performed by a person having an ordinary skill in the related art. However, this disclosure may be embodied in many different forms and is not to be construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%±5%, ±3%, or ±1% of the stated value.

As used herein, when a definition is not otherwise provided, “substituted” refers to replacement of hydrogen atom of a compound or a group by a substituent such as deuterium, a halogen atom, a hydroxy group, a nitro group, a cyano group, an amino group, an azido group, an amidino group, a hydrazino group, a hydrazono group, a C2 to C20 acyl group, a carbamyl group, a thiol group, an ester group, a carboxylic acid group or a salt thereof, a sulfonic acid group or a salt thereof, a phosphoric acid group or a salt thereof, a silyl group, a C1 to C20 alkyl group, a C2 to C20 alkenyl group, a C2 to C20 alkynyl group, a C6 to C30 aryl group, a C7 to C30 arylalkyl group (e.g., benzyl), a C1 to C30 alkoxy group, a C1 to C20 heteroalkyl group, a C3 to C20 heteroaryl group, a C4 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

As used herein, when a definition is not otherwise provided, “hetero” means including 1 to 4 heteroatoms selected from B, N, O, S, Se, Te, Ge, Si, and P.

Hereinafter, the term “combination” includes a mixture or a stacked structure of two or more.

As used herein, the term “alkyl” indicates a group derived from a completely saturated, branched or unbranched (or a straight or linear) hydrocarbon and having a specified number of carbon atoms.

As used herein, the term “alkoxy” represents “alkyl-O—”, wherein the term “alkyl” has the same meaning as described above.

As used herein, the term “alkenyl group” indicates a straight or branched chain, monovalent hydrocarbon group having at least one carbon-carbon double bond.

As used herein, the term “alkynyl group” indicates a straight or branched chain, monovalent hydrocarbon group having at least one carbon-carbon triple bond.

As used herein, the term “aryl” indicates an aromatic hydrocarbon containing at least one ring and having the specified number of carbon atoms.

As used herein, the term “arylalkyl” indicates a substituted or unsubstituted aryl group covalently linked to an alkyl group that is linked to a compound.

As used herein, the term “heteroaryl group” indicates an aryl group including carbon and at least one heteroatom as ring atoms.

As used herein, the term “heteroarylalkyl” indicates a substituted or unsubstituted heteroaryl group covalently linked to an alkyl group that is linked to a compound.

Hereinafter, a polishing slurry according to an embodiment is described in further detail.

The polishing slurry may be used to planarize a solid surface, such as the surface of a semiconductor substrate (including a thin film or a layer such as a dielectric layer or a metal layer), or to remove steps on a solid surface in the manufacturing process of a semiconductor device.

A polishing slurry according to an embodiment includes an abrasive, an oxidizing agent, and an additive.

The abrasive may be an abrasive particle capable of removing all or a portion of an object to be polished, and may be applied to a solid surface covered with the object to be polished to chemically and/or physically remove the object to be polished. The abrasive may have a predetermined hardness that enables it to remove the object to be polished, and may have, for example, a hardness higher than that of the object to be polished (e.g., a metal or a semi-metal) or an oxide thereof (e.g., a metal oxide or a semi-metal oxide).

The abrasive may be, for example, spherical, plate-shaped, linear, and/or irregularly shaped particles, and the particle size (average particle size, major axis, or length) of the abrasive may be, for example, in the range of about 1 nanometers (nm) to about 150 nm. The abrasive may include a fine abrasive, for example, of greater than or equal to about 1 nm and less than about 50 nm.

The abrasive may include, for example, an oxide abrasive, a nitride abrasive, a carbon abrasive, or a combination thereof, and may be silica, ceria, alumina, zirconia, titania, silicon nitride, silicon carbide (SiC), diamond, fullerene, derivatives thereof, or a combination thereof, but is not limited thereto.

The abrasive may be included in the polishing slurry in an amount of less than or equal to about 20 wt % based on the total weight of the polishing slurry, for example, about 0.001 wt % to about 20 wt %, about 0.001 wt % to about 15 wt %, about 0.001 wt % to about 10 wt %, about 0.001 wt % to about 8 wt %, about 0.001 wt % to about 5 wt %, about 0.001 wt % to about 3 wt %, about 0.01 wt % to about 2 wt %, about 0.1 wt % to about 1.5 wt %, about 0.2 wt % to about 1 wt %, or about 0.3 wt % to about 0.7 wt % based on the total weight of polishing slurry.

The oxidizing agent may oxidize the object to be polished, and for example, when applying the polishing slurry to the object to be polished including a metal or a semi-metal, the surface of the object to be polished may be oxidized to form a metal oxide or a semi-metal oxide. The object to be oxidized by the oxidizing agent (e.g., the metal oxide or semi-metal oxide) may have a relatively lower hardness and/or may be more brittle than the metal or semi-metal, and may be effectively removed by the abrasive due to the difference in mechanical strength between the object to be polished and the oxidized object to be polished.

The oxidizing agent is not limited as long as it is capable of oxidizing the object to be polished, and may include, for example, hydrogen peroxide, peracetic acid, percarbonates, urea peroxide, perchloride acid, persulfates, or the like, or a combination thereof.

The oxidizing agent may be included in the polishing slurry an amount of less than or equal to about 5 wt %, and within the above range, about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.5 wt %, about 0.01 wt % to about 0.3 wt %, about 0.02 wt % to about 0.1 wt %, or about 0.03 wt % to about 0.05 wt %, based on the total weight of the polishing slurry.

The additive may include a polymerization product of one or more types of histidine derivatives. The polymerization product of the histidine derivative (or the one or more types of histidine derivatives) may be a result of polymerization using the histidine derivative as a reactant or one of the reactants, and may include one or more repeating units (also referred to as a structural unit or repeating structural unit) derived from the histidine derivative. Herein, the polymerization may be, for example, radical polymerization and/or addition polymerization, but is not limited thereto. The polymerization product of the histidine derivative may act as a corrosion inhibitor in the polishing slurry, and may effectively prevent or reduce corrosion and/or over-etching of the object to be polished or an oxide of the object to be polished (oxidized by the oxidizing agent) during and/or after the polishing process.

The histidine derivative, which is a reactant or one of the reactants, may include a substituted or unsubstituted cyclic imide group or a substituted or unsubstituted amic acid group, instead of an amino group of substituted or unsubstituted histidine. The cyclic imide group may have a ring structure including two carbonyl groups bonded to nitrogen, and the amic acid group may have an acyclic structure including one or more amide groups and one or more carboxyl groups.

For example, the polymerization product of the histidine derivative may include a polymerization product of a first histidine derivative including a substituted or unsubstituted cyclic imide group, a polymerization product of a second histidine derivative including a substituted or unsubstituted amic acid group, a copolymerization product of the first histidine derivative and the second histidine derivative, or a combination thereof.

The polymerization product of the first histidine derivative may be obtained by polymerizing the first histidine derivative including a substituted or unsubstituted cyclic imide group as a reactant or one of the reactants and may include a repeating unit (structural unit) derived from the first histidine derivative.

The polymerization product of the second histidine derivative may be obtained by polymerizing the second histidine derivative including a substituted or unsubstituted amic acid group as a reactant or one of the reactants, and may include a repeating unit (structural unit) derived from the second histidine derivative.

The copolymerization product of the first histidine derivative and the second histidine derivative may be obtained, for example, by copolymerizing the first histidine derivative and the second histidine derivative as at least a portion of the reactants, and may include a repeating unit (structural unit) derived from the first histidine derivative and a repeating unit (structural unit) derived from the second histidine derivative.

A combination of the polymerization product of the first histidine derivative and the polymerization product of the second histidine derivative may be a mixture of the polymerization product of the first histidine derivative and the polymerization product of the second histidine derivative.

For example, the first histidine derivative may be represented by Chemical Formula 1-1:

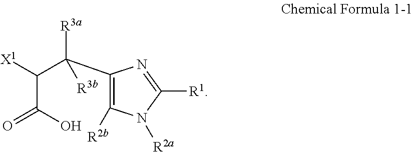

In Chemical Formula 1-1,
X¹ may be a substituted or unsubstituted cyclic imide group including a polymerizable unsaturated bond,
R¹, R^{2a}, R^{2b}, R^{3a}, and R^{3b} may each independently be hydrogen, deuterium, a substituted or unsubstituted C1 to C20 alkyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} may each independently be present or any two adjacent R¹, R^{2a}, R^{2b}, R^{3a}, and R^{3b} may be linked to form a ring.

The first histidine derivative may be obtained, for example, by reacting a histidine including a substituted or unsubstituted imidazole group and an amino group with a cyclic acid anhydride, and the substituted or unsubstituted cyclic imide group (X¹) of Chemical Formula 1-1 may be determined depending on the type of the cyclic acid anhydride. However, the first histidine derivative is not limited thereto, and may be obtained in various ways.

X¹ of Chemical Formula 1-1 may include at least one polymerizable unsaturated bond, for example, the polymerizable unsaturated bond may be included in the cyclic imide group or included in a substituent of the cyclic imide group. The polymerizable unsaturated bond may include, for example, a substituted or unsubstituted alkenyl(ene) group (ethenyl(ene) group or carbon-carbon double bond), a substituted or unsubstituted alkynyl(ene) group (ethynyl(ene) group or carbon-carbon triple bond), or a combination thereof.

For example, X¹ of Chemical Formula 1-1 may be represented by any one of Chemical Formulae A to D, but is not limited thereto:

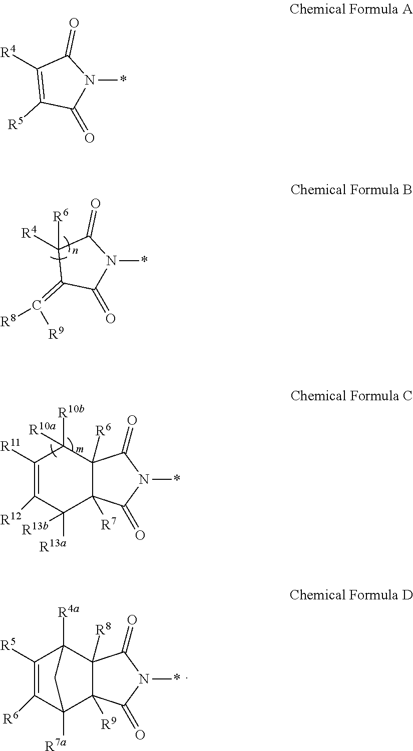

In Chemical Formulae A to D,
R⁴, R^{4a}, R⁵, R⁶, R⁷, R^{7a}, R⁸, R⁹, R^{10a}, R^{10b}, R¹¹, R¹², R^{13a}, and R^{13b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴, R^{4a}, R⁵, R⁶, R⁷, R^{7a}, R⁸, R⁹, R^{10a}, R^{10b}, R¹¹, R¹², R^{13a}, and R^{13b} may each independently be present or any two adjacent R⁴, R^{4a}, R⁵, R⁶, R⁷, R^{7a}, R⁸, R⁹, R^{10a}, R^{10b}, R¹¹, R¹², R^{13a}, and R^{13b} may be linked to form a ring,
n may be an integer of 1 to 5,
m may be an integer of 0 to 5, and
* may be a linking point with Chemical Formula 1-1.

For example, the second histidine derivative may be represented by Chemical Formula 1-2, but is not limited thereto:

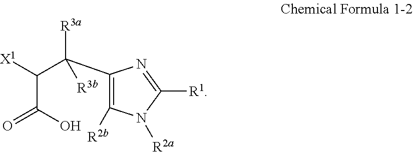

In Chemical Formula 1-2,
X² may be a substituted or unsubstituted amic acid group including a polymerizable unsaturated bond,
R¹, R^{2a}, R^{2b}, R^{3a}, and R^{3b} may each independently be hydrogen, deuterium, a substituted or unsubstituted C1 to C20 alkyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} may each independently be present or any two adjacent R¹, R^{2a}, R^{2b}, R^{3a}, and R^{3b} may be linked to form a ring.

The second histidine derivative may be obtained, for example, by a ring-opening reaction or the like when reacting a histidine including a substituted or unsubstituted imidazole group and an amino group with a cyclic acid anhydride, and the substituted or unsubstituted amic acid group (X²) of Chemical Formula 1-2 may be determined according to the type of the cyclic acid anhydride. However, it is not limited thereto, and the second histidine derivative may be obtained by various methods.

X² of Chemical Formula 1-2 may include at least one polymerizable unsaturated bond, and for example, the polymerizable unsaturated bond may be included between an amide group and a carboxyl group of the amic acid group, may be included in a substituent of a linking group between the amide group and the carboxyl group of the amic acid group, or may be included in a ring or a substituent of a ring formed by linking two adjacent substituents of the linking group. The polymerizable unsaturated bond may include, for example, a substituted or unsubstituted alkenyl(ene) group (ethenyl(ene) group or carbon-carbon double bond), a substituted or unsubstituted alkynyl(ene) group (ethynyl(ene) group or carbon-carbon triple bond), or a combination thereof.

For example, X² of Chemical Formula 1-2 may be represented by any one of Chemical Formulae E to H:

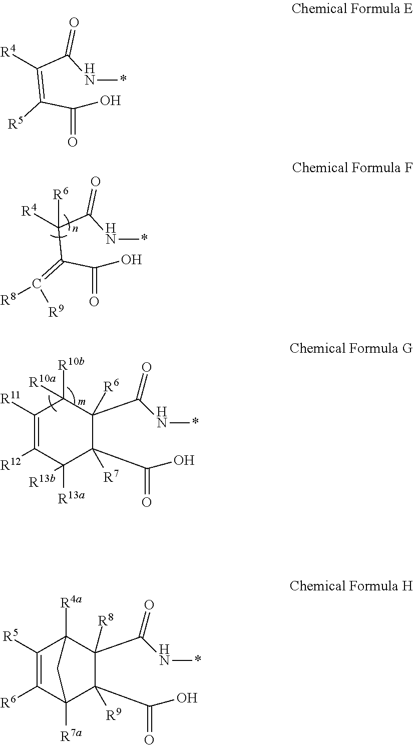

In Chemical Formulae E to H,
R⁴, R^{4a}, R⁵, R⁶, R⁷, R^{7a}, R⁸, R⁹, R^{10a}, R^{10b}, R¹¹, R¹², R^{13a}, and R^{13b} may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴, R^{4a}, R⁵, R⁶, R⁷, R^{7a}, R⁸, R⁹, R^{10a}, R^{10b}, R¹¹, R¹², R^{13a}, and R^{13b} may each independently be present or any two adjacent R⁴, R^{4a}, R⁵, R⁶, R⁷, R^{7a}, R⁸, R⁹, R^{10a}, R^{10b}, R¹¹, R¹², R^{13a}, and R^{13b} may be linked to form a ring,
n may be an integer of 1 to 5,
m may be an integer of 0 to 5, and
* may be a linking point with Chemical Formula 1-2.

For example, R¹, R^{2a}, R^{2b}, R^{3a}, and R^{3b} of Chemical Formula 1-1 or 1-2 may each independently be hydrogen, deuterium, a C1 to C20 alkyl group, a halogen-substituted C1 to C20 alkyl group, a substituted or unsubstituted phenyl group, a substituted or unsubstituted biphenyl group, a substituted or unsubstituted naphthyl group, a carboxyl group, a hydroxy group, a cyano group, a halogen (F, Cl, Br, or I), or a combination thereof.

For example, R¹, R^{2a}, R^{2b}, R^{3a}, and R^{3b} of Chemical Formula 1-1 or 1-2 may each independently be hydrogen, deuterium, a methyl group, an ethyl group, a propyl group, a butyl group, an ethenyl group, a propenyl group, a butenyl group, an ethynyl group, a propynyl group, a butynyl group, a halogen-substituted methyl group, a halogen-substituted ethyl group, a halogen-substituted propyl group, a halogen-substituted butyl group, a halogen-substituted ethenyl group, a halogen-substituted propenyl group, a halogen-substituted butenyl group, a halogen-substituted ethynyl group, a halogen-substituted propynyl group, a halogen-substituted butynyl group, a halogen-substituted phenyl group, a halogen-substituted biphenyl group, a halogen-substituted naphthyl group, a carboxyl group, a halogen (F, Cl, Br, or I), or a combination thereof.

For example, R¹, R^{2a}, R^{2b}, R^{3a}, and R^{3b} of Chemical Formula 1-1 or 1-2 may each independently be hydrogen.

For example, R⁴, R^{4a}, R⁵, R⁶, R⁷, R^{7a}, R⁸, R⁹, R^{10a}, R^{10b}, R¹¹, R¹², R^{13a}, and R^{13b} of Chemical Formulae A to H may each independently be hydrogen, deuterium, a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxy group, a cyano group, a halogen (F, Cl, Br, or I), or a combination thereof.

For example, R⁴, R^{4a}, R⁵, R⁶, R⁷, R^{7a}, R⁸, R⁹, R^{10a}, R^{10b}, R¹¹, R¹², R^{13a}, and R^{13b} of Chemical Formulae A to H may each independently be hydrogen, deuterium, a methyl group, an ethyl group, a propyl group, a butyl group, an ethenyl group, a propenyl group, a butenyl group, an ethynyl group, a propynyl group, a butynyl group, a halogen-substituted methyl group, a halogen-substituted ethyl group, a halogen-substituted propyl group, a halogen-substituted butyl group, a halogen-substituted ethenyl group, a halogen-substituted propenyl group, a halogen-substituted butenyl group, a halogen-substituted ethynyl group, a halogen-substituted propynyl group, a halogen-substituted butynyl group, a halogen-substituted phenyl group, a halogen-substituted biphenyl group, a halogen-substituted naphthyl group, a carboxyl group, a halogen (F, Cl, Br, or I), or a combination thereof.

For example, R⁴ and R⁵ of Chemical Formula A or E may each be hydrogen.

For example, one of R⁴ and R⁵ of Chemical Formula A or E may be hydrogen, and the other of R⁴ and R⁵ may be a C1 to C20 alkyl group, a halogen-substituted C1 to C20 alkyl group, a C2 to C20 alkenyl group, a halogen-substituted C2 to C20 alkenyl group, a C2 to C20 alkynyl group, a halogen-substituted C2 to C20 alkynyl group, a substituted or unsubstituted phenyl group, a substituted or unsubstituted biphenyl group, a substituted or unsubstituted naphthyl group, a carboxyl group, a hydroxy group, a cyano group, a halogen (F, Cl, Br, or I), or a combination thereof.

For example, R⁴ and R⁵ of Chemical Formula A or E may be linked to form a ring. Herein, the ring may include a substituted or unsubstituted C3 to C20 aliphatic ring, a substituted or unsubstituted C6 to C20 aromatic ring, or a combination thereof.

For example, R⁴, R⁶, R⁸, and R⁹ of Chemical Formula B or F may each be hydrogen.

For example, two of R⁴, R⁶, R⁸, and R⁹ of Chemical Formula B or F may be linked to form a ring. Herein, the ring may include a substituted or unsubstituted C3 to C20 aliphatic ring, a substituted or unsubstituted C6 to C20 aromatic ring, or a combination thereof.

For example, n of Chemical Formula B or F may each independently be 1, 2, or 3.

For example, m of Chemical Formula C or G may be 0, 1, 2, or 3.

The polymerization product of the histidine derivative may be obtained by polymerizing the histidine derivative as one of the reactants; for example, the polymerization reaction may be performed at about 25 °C to about 200 °C, and within the range, it may be performed at about 50 °C to about 180 °C, about 60 °C to about 160 °C, or about 80 °C to about 150 °C. A suitable polymerization initiator may be optionally added during the polymerization reaction.

The polymerization reaction of the histidine derivative may mainly occur at the substituted or unsubstituted cyclic imide group and/or the substituted or unsubstituted amic acid group where the polymerizable unsaturated bond is included, and according to the position of the polymerizable unsaturated bond, the structural unit derived from the histidine derivative may be positioned in a main chain or a side chain of the polymerization product.

The polymerization product of the histidine derivative may include one or more repeating units represented by, for example, one of Chemical Formulae 2-1 to 2-10, but is not limited thereto:

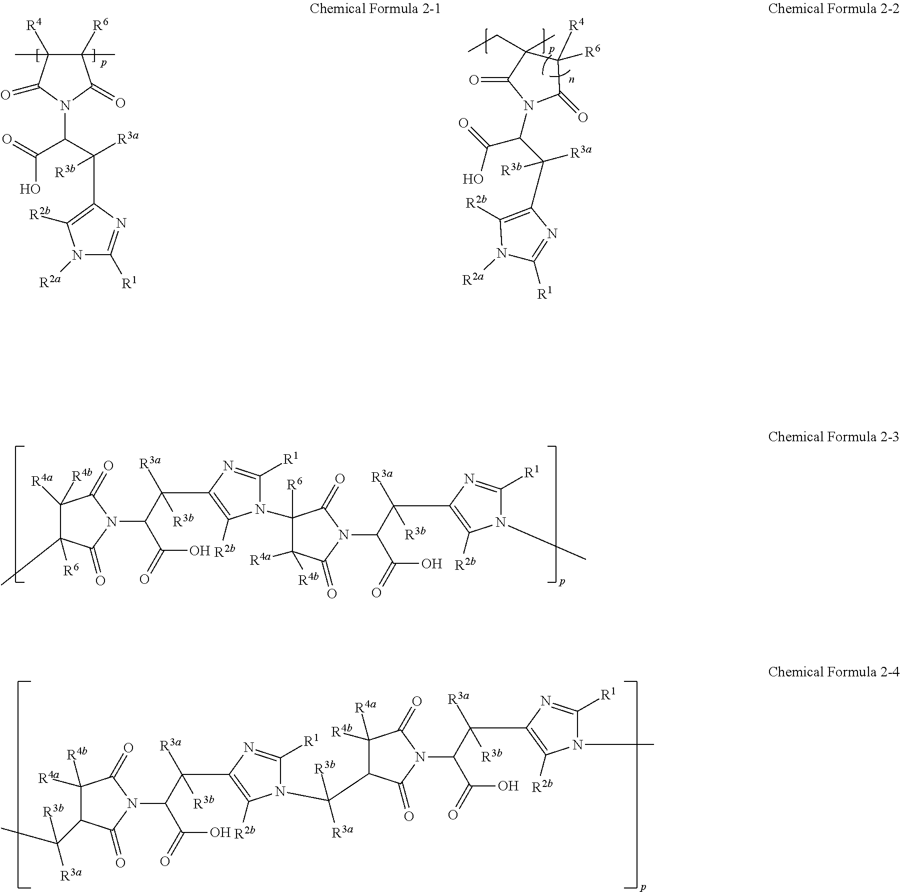

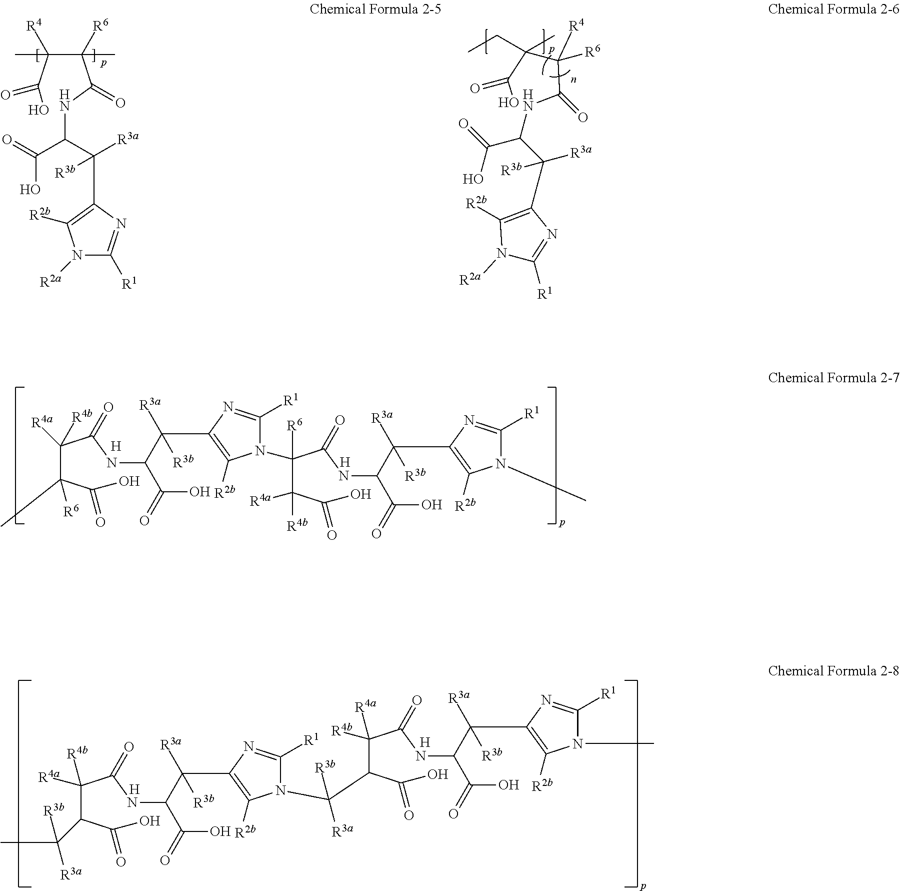

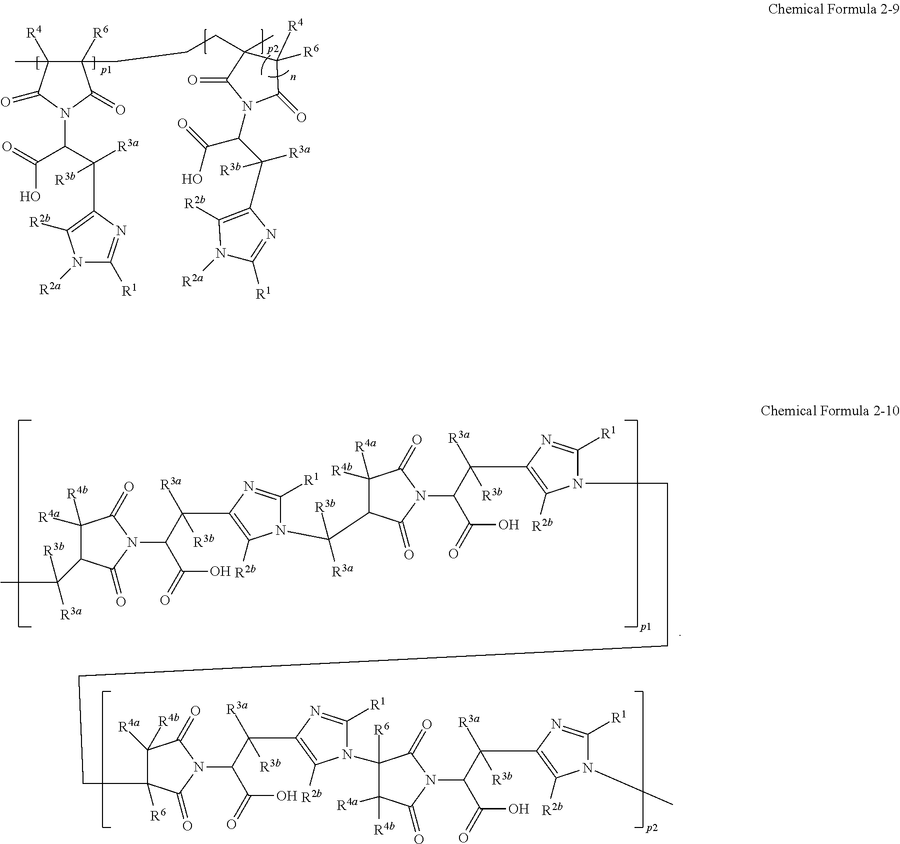

In Chemical Formulae 2-1 to 2-10,
R¹, R^{2a}, R^{2b}, R^{3a}, and R^{3b} may each independently be hydrogen, deuterium, a substituted or unsubstituted C1 to C20 alkyl group, a substituted or unsubstituted C1 to C20 alkoxy group, a substituted or unsubstituted C6 to C20 aryl group, a carboxyl group, a hydroxy group, a halogen, or a cyano group,
R^{4a}, R^{4b}, and R⁶ may each independently be hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group, and
p, p1, and p2 refer to the number of repeating units and may each independently be an integer of about 2 to 100.

The polymerization product of the histidine derivative may be included in an amount of less than or equal to about 5 wt % based on the polishing slurry, and within the range, it may be included in an amount of about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.5 wt %, about 0.005 wt % to 0.5 wt %, about 0.01 wt % to 0.4 wt %, or about 0.2 wt % to 0.3 wt %, based on the weight of the polishing slurry.

The polymerization product of the histidine derivative may be included at a concentration of less than or equal to about 0.1 mole per liter (mol/L) based on the polishing slurry, and within the range, it may be included at a concentration of about 0.001 to about 0.1 mol/L, about 0.001 to about 0.08 mol/L, about 0.001 to about 0.06 mol/L, about 0.001 to about 0.05 mol/L, about 0.003 to 0.04 mol/L, about 0.005 to 0.03 mol/L, about 0.007 to 0.02 mol/L, about 0.008 to 0.015 mol/L, or about 0.009 to 0.012 mol/L.

The oxidizing agent and the polymerization product of the histidine derivative may be included in an appropriate ratio so as to increase the polishing rate and lower corrosion or over-etching, and for example, the oxidizing agent and the polymerization product of the histidine derivative may be included in a molar ratio of about 0.01:10 to about 10:0.01 in the polishing slurry. Within the range, the oxidizing agent and the polymerization product of the histidine derivative may be included in a molar ratio of about 0.1:10 to about 10:0.1, about 1:10 to about 10:1, about 2:8 to about 8:2, about 3:7 to about 7:3, about 4:6 to about 6:4, or about 5:5.

The additive may further include an unpolymerized histidine derivative (monomer) in addition to the polymerization product of the histidine derivative. The histidine derivative may include the first histidine derivative, the second histidine derivative, or a combination thereof. The first histidine derivative may be represented by, for example, Chemical Formula 1-1, and X¹ of Chemical Formula 1-1 may be represented by any one of Chemical Formulae A to D. The second histidine derivative may be represented by, for example, Chemical Formula 1-2, and X² of Chemical Formula 1-2 may be represented by any one of Chemical Formulae E to H.

The histidine derivative may be included in an amount equal to or less than that of the polymerization product of the histidine derivative, and for example, the polymerization product of the histidine derivative and the histidine derivative may be included in a molar ratio of about 10:0 to about 5:5, about 9:1 to about 5:5, about 8:2 to about 5:5, about 7:3 to about 5:5, or about 6:4 to about 5:5 in the polishing slurry.

The additive may further include a chelating agent, a surfactant, a dispersant, a pH adjuster, a reaction catalyst, or a combination thereof.

The chelating agent may be, for example, phosphoric acid, nitric acid, citric acid, malonic acid, a salt thereof, or a combination thereof, but is not limited thereto.

The surfactant may be an ionic or nonionic surfactant, and for example, may be a copolymer of ethylene oxide, a copolymer of propylene oxide, an amine compound, or a combination thereof, but is not limited thereto.

The dispersant may facilitate dispersion of the abrasive and may include, for example, a water-soluble monomer, a water-soluble oligomer, a water-soluble polymer, a metal salt, or a combination thereof. A weight average molecular weight of the water-soluble polymer may be, for example, less than or equal to about 10,000 grams per mole (g/mol), for example, less than or equal to about 5000 g/mol, for example, less than or equal to about 3000 g/mol. The metal salt may be, for example, a copper salt, a nickel salt, a cobalt salt, a manganese salt, a tantalum salt, a ruthenium salt, or a combination thereof. The dispersant may be poly(meth)acrylic acid, poly(meth)acrylic maleic acid, polyacrylonitrile-co-butadiene-acrylic acid, carboxylic acids, sulfonic esters, sulfonic acid, phosphoric ester, cellulose, diol, a salt thereof, or a combination thereof, but is not limited thereto.

The pH regulator may adjust the pH of the polishing slurry and may be, for example, an inorganic acid or a salt thereof, an organic acid, a salt thereof, or a combination thereof. The inorganic acid or a salt thereof may include nitric acid, hydrochloric acid, phosphoric acid, sulfuric acid, hydrofluoric acid, hydrobromic acid, iodic acid, or a salt thereof, and organic acids or a salt thereof may include, but are not limited to, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or a salt thereof, but is not limited thereto. A base may be used to adjust the pH of the polishing slurry, for example an inorganic base such as potassium hydroxide or sodium hydroxide, but is not limited thereto.

The reaction catalyst may promote an oxidation reaction of the object to be polished by catalyzing decomposition of the oxidizing agent. The reaction catalyst may be, for example, a metal ion compound capable of effectively generating radicals, and may be, for example, a catalyst used in a Fenton reaction or a Fenton-like reaction. The reaction catalyst may include, for example, a cation including an iron (Fe) ion, a chromium (Cr) ion, a manganese (Mn) ion, a cobalt (Co) ion, a cerium (Ce) ion, a potassium (K) ion, a silver (Ag) ion, a copper (Cu) ion, a molybdenum (Mo) ion, a niobium (Nb) ion, a nickel (Ni) ion, an osmium (Os) ion, a lead (Pb) ion, a tin (Sn) ion, a titanium (Ti) ion, a vanadium (V) ion, or a combination thereof, and an anion including a nitrate, a sulfate, a fluoride, a chloride, a bromide, an iodide, a fluorate, a chlorate, a bromate, an iodate, a perchlorate, a perbromate, a periodate, a cyanide salt, an oxalate, a citrate, an acetate, an acetylacetonate, a gluconate, or a combination thereof, but is not limited thereto. For example, the reaction catalyst may be an iron ion catalyst, such as iron(II) nitrate, iron(III) nitrate, iron(II) sulfate, iron(III) sulfate, iron(II) oxalate, iron(III) oxalate, or a combination thereof, but is not limited thereto.

Each component of the additive (other than the first histidine derivative, the second histidine derivative, or a combination thereof) may each independently be included in trace amounts, for example, from about 1 parts per million (ppm) to about 100,000 ppm, but is not limited thereto.

The polishing slurry may further include a dispersion medium or solvent (hereinafter referred to as “dispersion medium”) capable of dispersing and/or dissolving the above-described components, and the dispersion medium may be, for example, water. The water may be, for example, distilled water and/or deionized water. The dispersion medium may be included as a balance amount excluding solids such as abrasives, oxidizing agents, and additives.

The pH of the polishing slurry may be about 1.0 to about 10.0, and within the above range may be about 1.0 to about 7.0 or about 1.0 to about 5.0.

The polishing slurry may be used in the formation of various structures, for example, it may be used in the polishing process of a conductive material such as a metal layer, or an insulating material such as a shallow trench isolation (STI) or an insulating layer. For example, the polishing slurry may be used to polish a conductive material such as a metal wire, a via, and/or an electrode in a semiconductor substrate, and may be used to polish a conductive material such as tungsten, molybdenum, aluminum, copper, nickel, or alloys thereof, and may be used to polish a molybdenum (Mo) containing layer or a molybdenum alloy.

An example of a method of manufacturing a semiconductor device according to an embodiment using the polishing slurry is described below.

A method of manufacturing a semiconductor device according to an embodiment includes performing chemical mechanical polishing (CMP) on all or a portion of a surface of an object to be polished. The object to be polished may be a variety of structures, for example, a semiconductor substrate such as a silicon wafer (including a thin film or a layer such as an insulating layer or a metal layer), and the polishing surface may include a metal such as molybdenum, aluminum, copper or nickel, an alloy thereof, or a metal oxide or semi-metal oxide generated during a chemical-mechanical polishing process; an oxide such as silicon oxide or molybdenum oxide; a nitride such as silicon nitride, aluminum nitride, titanium nitride or gallium nitride; a carbide such as silicon carbide; an elemental semiconductor such as silicon or germanium; a compound semiconductor such as indium phosphide (InP), gallium arsenide (GaAs); an organic or inorganic compound such as tetraethylorthosilicate (TEOS); or a combination thereof.

For example, the polishing slurry may be used to polish a conductive material such as a metal layer in a semiconductor substrate, and may be used to form a metal wire from a conductive layer including, for example, molybdenum (Mo) or a Mo alloy. The metal wire may be embedded in the trench of the dielectric layer.

Hereinafter, an example of a method of manufacturing a semiconductor device using the aforementioned polishing slurry is described in further detail.

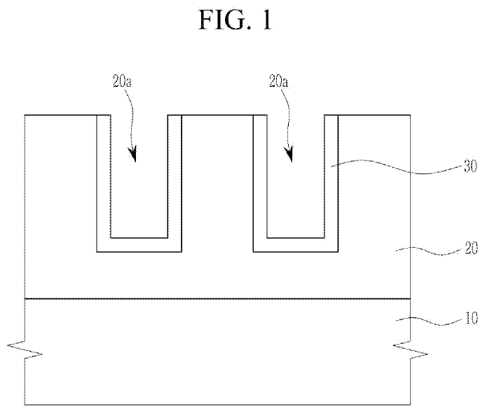

FIGS. 1 to 4 are cross-sectional views showing an example of a method of manufacturing a semiconductor device according to an embodiment.

Referring to FIG. 1, a dielectric layer 20 is formed on a semiconductor substrate 10. The dielectric layer 20 may include an oxide, a nitride, and/or an oxynitride. Subsequently, the dielectric layer 20 is etched to form a trench or a hole 20a (hereinafter, referred to as a “trench”). The width of the trench 20a may be less than about 50 nm, and within the above range, it may be greater than or equal to about 1 nm and less than about 50 nm, about 1 nm to about 40 nm, about 1 nm to about 30 nm, about 1 nm to about 20 nm, about 1 nm to about 15 nm, about 1 nm to about 10 nm, or about 1 nm to about 8 nm. Subsequently, a barrier layer 30 is formed on the inside wall of the trench 20a. The barrier layer 30 may include, for example, titanium (Ti), tantalum (Ta), titanium nitride (TiN), and/or tantalum nitride (TaN), but is not limited thereto.

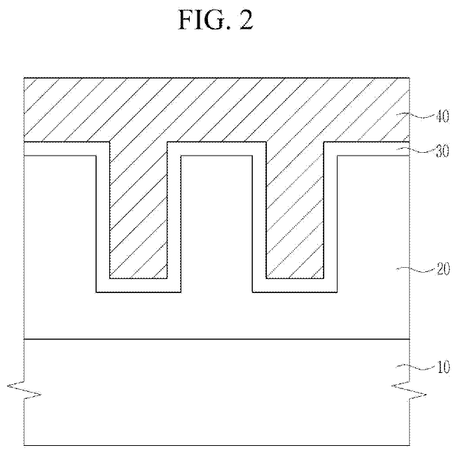

Referring to FIG. 2, the inside and top of the trench 20a are filled or coated with a metal to form a conductive layer 40. The conductive layer 40 may include, for example, molybdenum, tungsten, aluminum, copper, nickel, an alloy thereof, or a combination thereof.

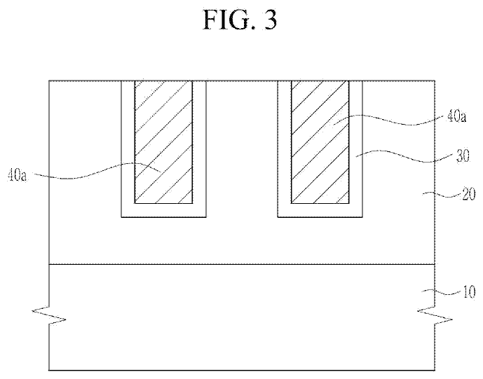

Referring to FIG. 3, the surface of the conductive layer 40 is planarized to substantially match the surface of the dielectric layer 20 to form an embedded conductive pattern 40a. The planarization may be performed by chemical mechanical polishing (CMP) using CMP equipment, and the polishing slurry described above may be used. CMP equipment will be described below. For example, when the barrier layer 30 is a Ta layer and the conductive layer 40 is a molybdenum (Mo)-containing layer, a higher polishing selectivity of Ta relative to Mo of the polishing slurry is preferred, for example, higher than about 50:1.

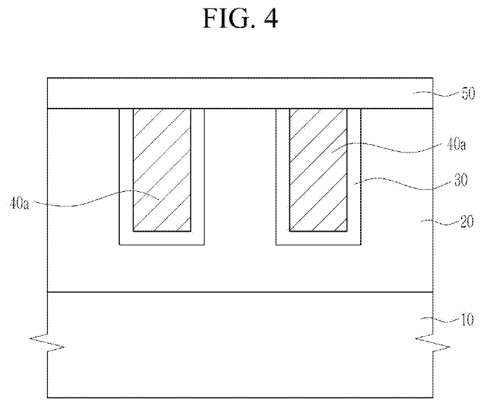

Referring to FIG. 4, a capping layer 50 is formed on the embedded conductive pattern 40a and the dielectric layer 20. The capping layer 50 may include SiN and/or SiC, but is not limited thereto.

Hereinafter, the planarization for forming the embedded conductive pattern 40a is described. The planarization may be performed by CMP using a CMP equipment as described above.

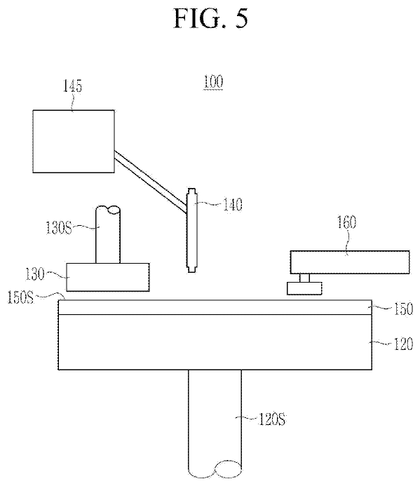

FIG. 5 is a schematic view showing CMP equipment according to an example.

Referring to FIG. 5, CMP equipment 100 according to an example may include, for example, a lower base (not shown); a platen 120 rotatably provided on an upper surface of the lower base; a polishing head 130; a polishing pad 150 on the platen 120; a pad conditioner 160; and at least one polishing slurry supply device 140 disposed adjacent to the polishing pad 150 to supply polishing slurry to the polishing pad 150.

The platen 120 may be provided rotatably on the surface of the lower base. For example, the platen 120 may receive rotational power from a motor (not shown) disposed in the lower base, and accordingly may rotate in a certain direction, such as clockwise or counterclockwise, by a rotation axis 120S perpendicular to the surface of the platen 120.

The polishing head 130 may be disposed on the platen 120 and may hold a body to be polished. The body to be polished may be a semiconductor substrate 10, such as a wafer. The polishing head 130 may include a rotating shaft 130S that rotates the body to be polished. When performing polishing, the rotation direction of the polishing head 130 may be opposite to the rotation direction of the platen 120.

The polishing pad 150 may be disposed on the platen 120 so as to be supported by the platen 120. The polishing pad 150 may rotate together with the platen 120. The polishing pad 150 may have a roughly formed polishing surface 150S. This polishing surface 150S may mechanically polish the surface of the semiconductor substrate 10 by directly contacting the semiconductor substrate 10. The polishing pad 150 may be made of a porous material with a plurality of microspaces, and the plurality of microspaces may accommodate polishing slurry. The polishing surface 150S of the polishing pad 150 may include a surface that directly contacts the body to be polished and a predetermined depth therefrom, and the predetermined depth may be about 10% to about 100%, about 20% to about 100%, about 30% to about 100%, about 40% to about 100%, or about 50% to about 100% of the thickness of the polishing pad 150. The polishing surface 150S of the polishing pad 150 may be flat, for example. The polishing surface 150S of the polishing pad 150 may have, for example, protrusions or grooves.

A pad conditioner 160 may be adjacent to the polishing pad 150 and may maintain the state of the polishing surface 150S so that the surface of the semiconductor substrate 10 may be effectively polished while the polishing process is performed.

The polishing slurry supply device 140 may be adjacent to the polishing pad 150 and may supply polishing slurry from the polishing slurry tank 145 and supply the polishing slurry to the polishing pad 150. The polishing slurry supply device 140 may include a nozzle capable of supplying polishing slurry onto the polishing pad 150 during the polishing process. The polishing slurry supply device 140 may supply the polishing slurry.

CMP may be performed, for example, by disposing a semiconductor substrate 10 and a polishing pad 150 so as to face each other, supplying the polishing slurry between the semiconductor substrate 10 and the polishing pad 150 from a polishing slurry supply device 140, and performing polishing by contacting the polishing pad 150 with the surface of the semiconductor substrate 10.

For example, the supplying of the polishing slurry may be performed at a rate of, for example, about 10 milliliters per minute (mL/min) to about 300 mL/min.

The performing of polishing may be performed by mechanical friction by contacting the polishing pad 150 with the surface of the semiconductor substrate 10 and rotating it. For example, a pressure of about 1 pound per square inch (psi) (about 6.89 kilopascals) to about 5 psi (about 34.47 kilopascals) may be applied during the polishing.

For example, the oxidizing agent of the polishing slurry may oxidize a surface of the object to be polished (e.g., a metal such as molybdenum) to form a metal oxide (e.g., molybdenum oxide) at a predetermined thickness in the object to be polished, and in the performing of polishing, the abrasive may perform polishing by physically and/or chemically removing the metal oxide on the polishing surface. The polymerization product of histidine derivative of the polishing slurry may effectively prevent or reduce defects caused by excessive corrosion or over-etching of the surface of the object to be polished (e.g., a metal such as molybdenum) during the polishing as a corrosion inhibitor. Oxidation and prevention of corrosion or over-etching of the polishing surface may be performed simultaneously or sequentially.

In this way, the polishing slurry may increase the polishing rate of the object to be polished, while effectively reducing or preventing loss or defects caused by excessive corrosion or over-etching by including the abrasive, the oxidizing agent, and the polymerization product of the histidine derivative.

For example, the conductive layer may include a Mo-containing conductive layer, and the removal rate (RR) of the Mo-containing conductive layer may be greater than or equal to about 30 angstroms per minute (Å/min), and within the above range, may be about 30 Å/min to about 2000 Å/min, about 40 Å/min to about 2000 Å/min, about 50 Å/min to about 2000 Å/min, about 60 Å/min to 1000 Å/min, about 70 Å/min to 500 Å/min, about 80 Å/min to 320 Å/min, or about 90 Å/min to 200 Å/min, and the static etching rate (SER) of the Mo-containing conductive layer may be less than about 10 Å/min, and within the above range, may be greater than or equal to 0 Å/min and less than about 10 Å/min, 0 Å/min to about 8 Å/min, or 0 Å/min to about 6 Å/min. For example, the ratio of the removal rate to the etching rate of the Mo-containing conductive layer may be greater than or equal to about 40, and within the above range, may be about 40 to 3000, about 50 to about 3000, about 60 to about 2500, about 70 to about 2300, about 80 to about 2200, about 80 to about 2100, about 80 to about 2050, about 40 to 1500, about 50 to 1000, about 60 to 500, or about 70 to 420.

Although a method of manufacturing a semiconductor device according to an example is described above, it is not limited thereto, and may be applied to semiconductor devices with various structures.

The semiconductor device manufactured as described above may be included in an integrated circuit device. The integrated circuit device may be, for example, a dynamic random-access memory (DRAM) or logic device, but is not limited thereto. The integrated circuit device may include, for example, a unit device including a transistor, a capacitor, a diode, a resistor, or a combination thereof. For example, the transistor may have various structures, and may be, for example, a fin field-effect transistor (FinFET), gate-all-around field-effect transistor (GAAFET), multi-bridge channel field-effect transistor (MBCFET), complementary field-effect transistor (CFET), or vertical field-effect transistor (VFET), but is not limited thereto.

The integrated circuit device may be included in various electronic devices. The electronic device may include, for example, a mobile device, a computer, a laptop, a tablet PC, a smart watch, a sensor, a digital camera, an electronic book, a network device, a vehicle navigation, an Internet of Things (IoT) device, an Internet of Everything (IoE) device, a drone, a door lock, a safe, an automated teller machine (ATM), a security device, a medical device, a display device, or an automotive electronic component, but is not limited thereto

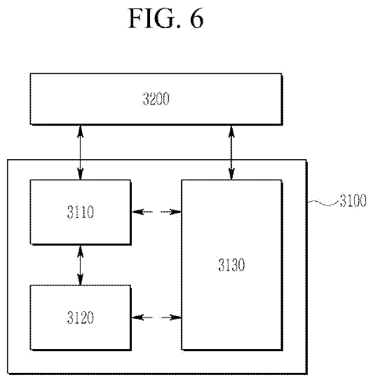

FIG. 6 is a conceptual view showing an example of an electronic device according to an embodiment.

Referring to FIG. 6, the electronic device 3100 according to an embodiment may include a memory unit 3110, an arithmetic logic unit 3120, and a control unit 3130, and these may be electrically connected. For example, the memory unit 3110, the arithmetic logic unit 3120, and the control unit 3130 may be implemented as one integrated circuit device (semiconductor chip), and, for example, may be monolithically integrated on a single substrate and implemented as a single integrated circuit device (semiconductor chip). The memory unit 3110, the arithmetic logic unit 3120, and the control unit 3130 may each independently include a transistor, a capacitor, a diode, a resistor, or a combination thereof. The electronic device 3100 may be connected to one or more input/output devices 3200.

Hereinafter, the embodiments are illustrated in more detail with reference to examples. However, these examples are exemplary, and the scope of claims is not limited thereto.

### EXAMPLES

### Synthesis Examples

### Synthesis Example 1

### (1) Synthesis of Monomer

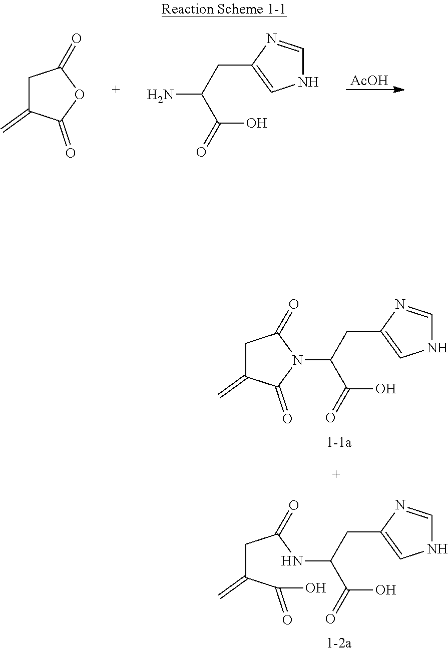

In a 250 milliliters (mL) round-bottom flask, 3 grams (g) of itaconic anhydride is dissolved in 20 mL of acetic acid to prepare an itaconic anhydride solution. In another flask, 4.0 g of L-histidine (Sigma-Aldrich) is dissolved in 30 mL of acetic acid to prepare a histidine solution, and the histidine solution is added dropwise to the itaconic anhydride solution. The reaction is performed overnight at room temperature. The obtained reaction product is precipitated in acetone, the acetone is discarded, and a precipitate is obtained. Subsequently, the precipitate is dissolved in water and re-precipitated twice in acetone to obtain 5.97 g of a mixture of Compound 1-1a and Compound 1-2a in a crystalline powder form. The yield is 93%.

¹H NMR (D₂O, 500 MHz), δ (ppm): 3.02 (1H, dd), 3.1-3.3 (1H, dd, 2H, s), 4.46 (1H, t), 5.67 (1H, s), 6.17 (1H, s), 7.14 (1H, s), 8.48 (1H, s).

¹H NMR (DMSO-d₆, 500 MHz), δ (ppm): 2.84 (1H, dd), 2.92 (1H, dd) 3.11 (2H, s), 4.38 (1H, t), 5.60 (1H, s), 6.07 (1H, s), 6.82 (1H, s), 7.60 (1H, s, 8.12 (1H, d).

### (2) Synthesis of Polymerization Product

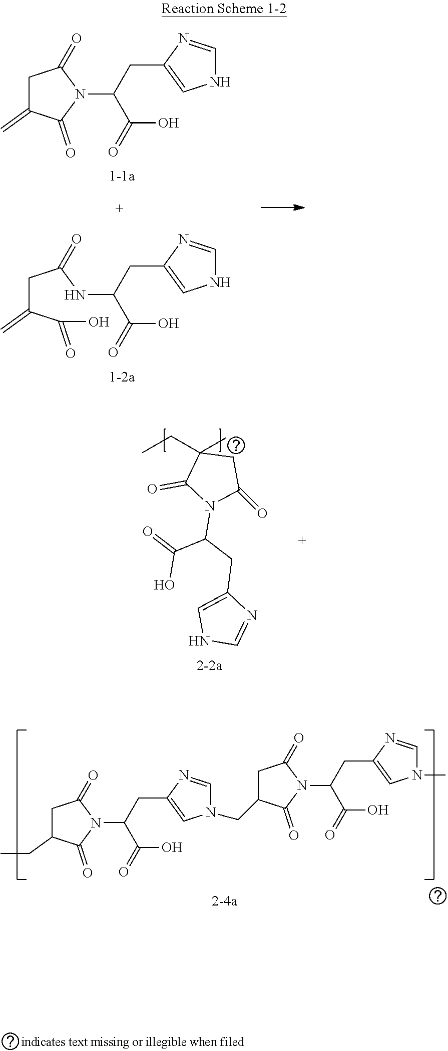

In a 20 mL glass vial, 1 g of a mixture of Compound 1-1a and Compound 1-2a is completely dissolved in 6 mL of water at 90 °C under magnetic stirring to prepare a solution. Subsequently, the solution is purged with N₂ for 10 minutes, and 0.01 g of ammonium persulfate solution (APS) dissolved in 0.05 ml of water is added thereto to initiate polymerization. The polymerization is performed at 90 °C for 20 hours under a nitrogen atmosphere. Subsequently, the obtained product is precipitated in acetone, filtered, washed with acetone, and dried overnight in a vacuum oven at 70 °C to obtain polymerization products (2-2a, 2-4a).

¹H NMR (D₂O, 500 MHz), δ (ppm): 2.3-2.7 (br), 2.8-3.7 (br), 3.8-4.0 (br), 4.2-4.5 (br), 7.1-7.5 (br), 8.5-8.9 (br).

FT-IR (cm⁻¹): 3131, 2918, 2586, 1776 (imide), 1699 (imide), 1585, 1390, 1350, 1160, 1090, 966, 837, 799.

### Synthesis Example 2

### (1) Synthesis of Monomer

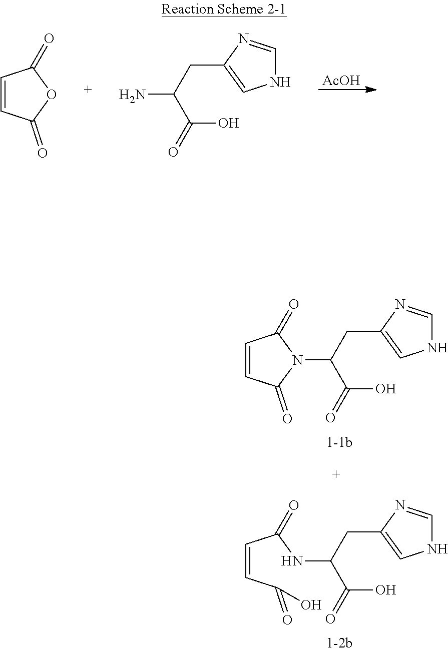 [SMILES: "AcOH" ; O=C1C=CC(=O)O1 ; NC(Cc1c[nH]cn1)C(=O)O ; O=C(O)C(Cc1c[nH]cn1)N1C(=O)C=CC1=O ; O=C(O)/C=C\C(=O)NC(Cc1c[nH]cn1)C(=O)O]

In a 250 mL round-bottom flask, 2.557 g of maleic anhydride is dissolved in 40 mL of acetic acid to prepare a maleic anhydride solution. In another flask, 4.0 g of L-histidine is dissolved in 40 mL of acetic acid to prepare a histidine solution, and the histidine solution is added dropwise to the maleic anhydride solution. The reaction is performed overnight at room temperature. The obtained reaction product is precipitated in acetone, the acetone is discarded, and a precipitate is obtained. Subsequently, the precipitate is dissolved in water and re-precipitated twice in acetone to obtain 5.29 g of a mixture of Compound 1-1b and Compound 1-2b in a crystalline powder form. The yield is 81%.

¹H NMR (D₂O, 500 MHz), δ (ppm): 3.11 (1H, dd), 3.21 (1H, dd), 4.56 (1H, t), 6.28 (2H, s), 7.18 (1H, s), 8.49 (1H, s).

¹H NMR (DMSO-d₆, 500 MHz), (ppm): 2.95 (1H, dd), 3.06 (1H, dd), 4.51 (1H, t), 6.23 (1H, d), 6.31 (1H, d), 6.99 (1H, s), 7.93 (1H, s), 9.53 (1H, br), 12.85 (2H, br).

### (2) Synthesis of Polymerization Product

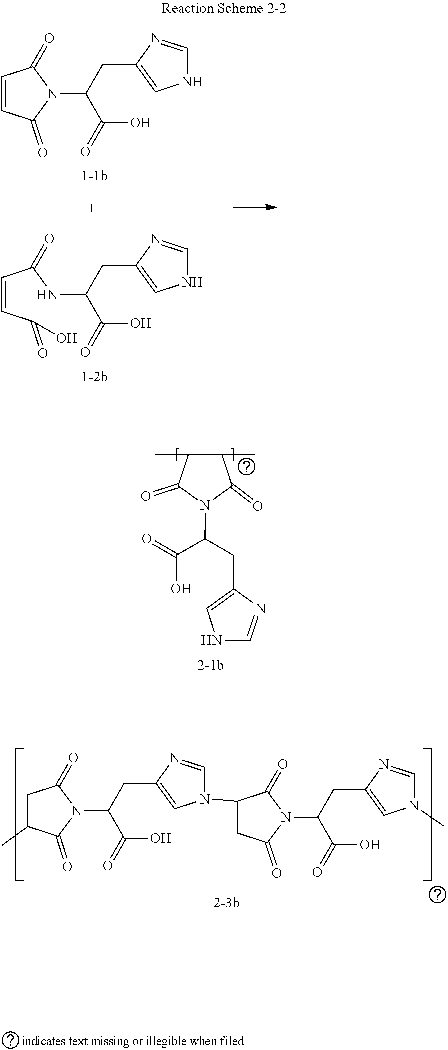

In a 50 mL round-bottom flask, 1.5 g of a mixture of Compound 1-1b and Compound 1-2b is completely dissolved in 7.5 mL of dimethyl sulfoxide (DMSO) at 80 °C under magnetic stirring to prepare a solution. Subsequently, the solution is purged with N₂ for 10 minutes, and 0.015 g of 2,2-azobisisobutyronitrile (AIBN) is added thereto to initiate polymerization. The polymerization is performed at 80 °C for 24 hours under a nitrogen atmosphere. Subsequently, the obtained product is precipitated in acetone, filtered, washed with acetone, and dried overnight in a vacuum oven at 70 °C to obtain polymerization products (2-1b, 2-3b).

¹H NMR (D₂O, 500 MHz), δ (ppm): 2.8-3.7 (br), 4.7-5.0 (br), 5.5-5.8 (br), 6.6 (br), 6.75 (br), 7.1-7.5 (br), 8.4-8.6 (br), 8.7-9.0 (br).

FT-IR (cm⁻¹): 3134, 2935, 2583, 1790 (imide), 1709 (imide), 1601, 1388, 1350, 1157, 1053, 953, 802.

### Synthesis Example 3

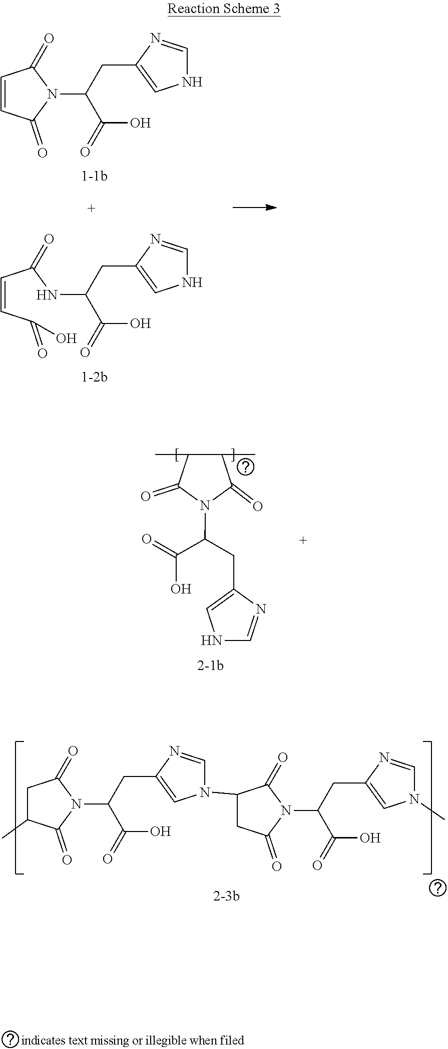

In a 20 mL glass vial, 1 g of a mixture of Compound 1-1b and Compound 1-2b is completely dissolved in 5 mL of DMSO at 80 °C under magnetic stirring to prepare a solution. The polymerization is performed at 80 °C for 42 hours. Subsequently, the obtained product is precipitated in acetone, filtered, washed with acetone, and dried overnight in a vacuum oven at 70 °C to obtain polymerization products (2-1b, 2-3b).

¹H NMR (D₂O, 500 MHz), δ (ppm): 2.8-3.6 (br), 3.8-4.0 (br), 4.7-5.0 (br), 5.5-5.8 (br), 6.6 (br), 6.8 (br), 7.1-7.5 (br), 8.5 (br), 8.6-9.0 (br).

FT-IR (cm⁻¹): 3138, 2948, 2590, 1789 (imide), 1709 (imide), 1604, 1388, 1351, 1158, 1053, 954, 836.

### Synthesis Example 4

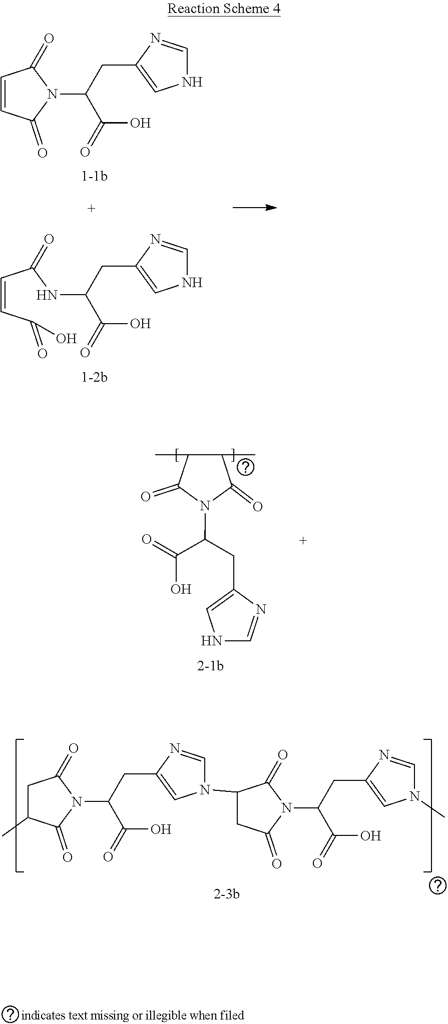

In a 20 mL glass vial, 1 g of a mixture of Compound 1-1b and Compound 1-2b is completely dissolved in 5 g of benzoic acid at 120 °C under magnetic stirring to prepare a solution. The polymerization is performed at 140 °C for 0.5 hours. Subsequently, the obtained product is dissolved in water, precipitated in acetone, filtered, washed with acetone, and dried overnight in a vacuum oven at 70 °C to obtain polymerization products (2-1b, 2-3b).

¹H NMR (D₂O, 500 MHz), δ (ppm): 2.8-3.5 (br), 3.9 (br), 4.4-4.6 (br), 5.2 (br), 5.4 (br), 7.1-7.5 (br), 8.4-8.6 (br), 8.6-9.0 (br).

FT-IR (cm⁻¹): 3135, 3033, 2594, 1706 (imide), 1605, 1543, 1384, 1162, 955, 835.

### Synthesis Example 5

### (1) Synthesis of Deep Eutectic Solvent-1 (DES-1)

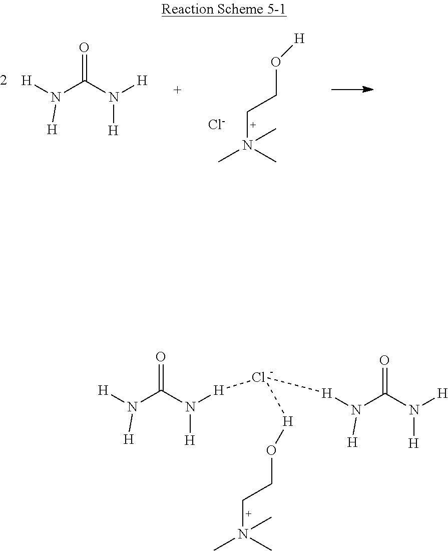

Choline chloride is mixed with urea (NH₂CONH₂) and heated at 110 °C while stirring until a clear melt is formed to obtain DES-1.

### (2) Synthesis of Polymerization Product

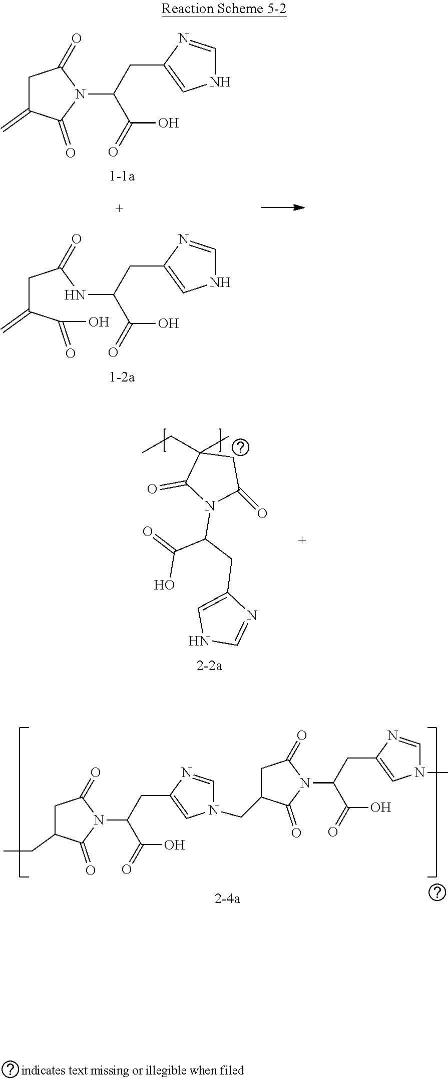

In a 100 mL glass reactor, 10 g of a mixture of Compound 1-1a and Compound 1-2a is completely dissolved in 40 g of DES-1 at 100 °C using a magnetic stirrer to prepare a solution. Subsequently, the solution is purged with N₂ for 10 minutes, and 1 mL of a t-butyl hydroperoxide (TBHP) solution is added thereto to initiate polymerization. The polymerization is performed at 100 °C for 17 hours under a nitrogen atmosphere. Subsequently, the obtained product is precipitated in ethanol and filtered, washed with ethanol and acetone, and dried overnight in a vacuum oven at 70 °C to obtain polymerization products (2-2a, 2-4a).

¹H NMR (D₂O, 500 MHz), δ (ppm): 1.0-2.0 (br), 2.2-3.0 (br), 3.2-3.4 (br), 4.1-4.5 (br), 6.9-7.3 (br), 8.3-8.5 (br).

FT-IR (cm⁻¹): 3141, 3028, 2616, 1694 (imide), 1596, 1381, 1351, 1204, 1088, 953, 801.

### Synthesis Example 6

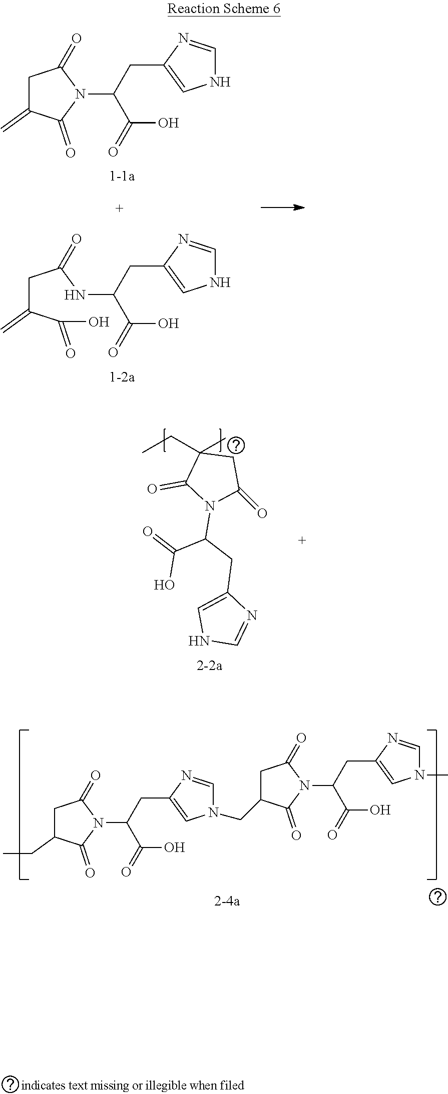

In a 20 mL glass vial, 1 g of a mixture of Compound 1-1a and Compound 1-2a is completely dissolved in 5 mL of DMSO at 120 °C using a magnetic stirrer to prepare a solution. Subsequently, the solution is purged with N₂ for 10 minutes, and 0.01 g of 2,2-azobisisobutyronitrile (AIBN) is added thereto to initiate polymerization. The polymerization is performed at 120 °C for 14 hours under a nitrogen atmosphere. Subsequently, the obtained product is precipitated in acetone, filtered, washed with acetone, and dried overnight in a vacuum oven at 70 °C to obtain polymerization products (2-2a, 2-4a).

¹H NMR (D₂O, 500 MHz), δ (ppm): 1.9 (s) 2.4-2.6 (br), 2.8-3.1 (br), 3.2-3.5 (br), 4.3-4.5 (br), 5.67 (s), 6.17 (s), 6.35 (s), 7.0-7.4 (br), 8.5-8.8 (br).

FT-IR (cm⁻¹): 3139, 3102, 2928, 2586, 1699 (imide), 1600, 1390, 1353, 1204, 1160, 1092, 837.

### Synthesis Example 7

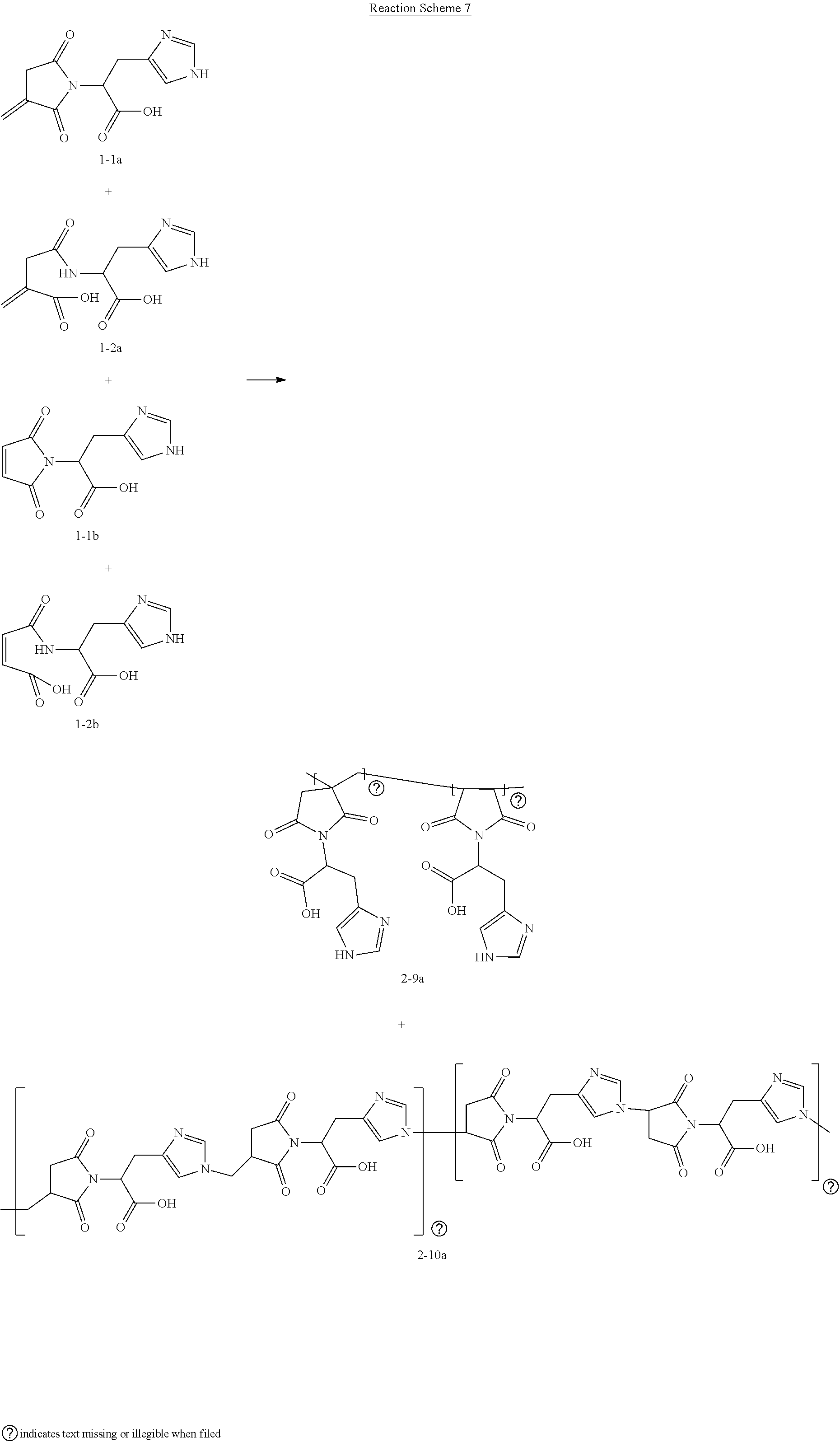

In a 20 mL glass vial, 0.5 g of a mixture of Compound 1-1a and Compound 1-2a and 0.5 g of a mixture of Compound 1-1b and Compound 1-2b are completely dissolved in 5 mL of DMSO at 120 °C using a magnetic stirrer to prepare a solution. The polymerization is performed at 120 °C for 14 hours. Subsequently, the obtained product is precipitated in acetone, filtered, washed with acetone, and dried overnight in a vacuum oven at 70 °C to obtain polymerization products (2-9a, 2-10a).

¹H NMR (D₂O, 500 MHz), δ (ppm): 1.91 (s) 2.4-2.6 (br), 2.8-3.0 (br), 3.1-3.5 (br), 4.3-4.5 (br), 5.6-5.8 (br), 6.17 (s), 6.36 (s), 7.0-7.4 (br), 8.4-8.8 (br).

FT-IR (cm⁻¹): 3141, 3016, 2605, 1774, 1699 (imide), 1597, 1387, 1352, 1202, 1091, 834, 800.

### Synthesis Example 8

### (1) Synthesis of Deep Eutectic Solvent-2 (DES-2)

Choline chloride is mixed with ethylene glycol and heated at 100 °C while stirring until a clear melt is formed to obtain DES-2.

### (2) Synthesis of Polymerization Product

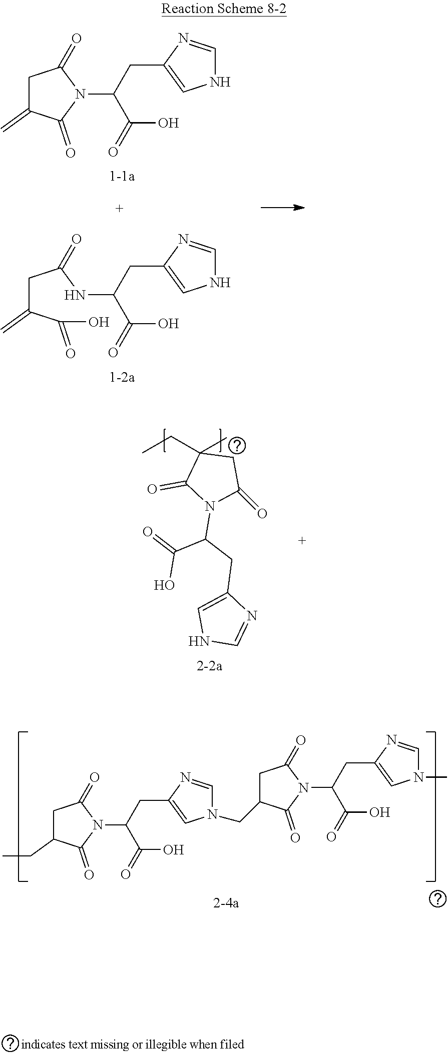

In a 100 mL glass reactor, 5 g of a mixture of Compound 1-1a and Compound 1-2a is completely dissolved in 53 g of DES-2 at 100 °C using a magnetic stirrer to prepare a solution. Subsequently, the solution is purged with N₂ for 10 minutes, and 0.5 mL of a t-butyl hydroperoxide (TBHP) solution is added thereto to initiate polymerization. The polymerization is performed at 100 °C for 24 hours under a nitrogen atmosphere.

Subsequently, the obtained product is precipitated in ethanol, filtered, washed with ethanol and acetone, and dried overnight in a vacuum oven at 70 °C to obtain polymerization products (2-2a, 2-4a).

¹H NMR (D₂O, 500 MHz), δ (ppm): 1.4-1.8 (br), 2.3-2.6 (br), 2.7-3.0 (br), 3.2-3.4 (br), 3.7 (br), 4.1 (br), 4.4 (br), 7.1 (br), 8.5 (br).

FT-IR (cm⁻¹): 3138, 2970, 1772 (imide), 1698 (imide), 1598, 1392, 1351, 1162, 1086, 957, 837.

### Preparation Example I

### Preparation Example 1

0.5 wt % of colloidal silica (an average particle diameter: about 30 nm), 0.034 wt % (0.01 mole per Liter (mol/L)) of hydrogen peroxide, 0.249 wt % (0.01 mol/L) of the polymerization products (2-2a, 2-4a) obtained in Synthesis Example 1, and the balance of deionized water are mixed to prepare a polishing slurry of pH 2.0.

### Preparation Example 2

A polishing slurry is prepared in the same manner as in Preparation Example 1, except that 0.235 wt % (0.01 mol/L) of the polymerization products (2-1b, 2-3b) obtained in Synthesis Example 2 are included instead of the polymerization products (2-2a, 2-4a) obtained in Synthesis Example 1.

### Preparation Example 3

A polishing slurry is prepared in the same manner as in Preparation Example 1, except that 0.235 wt % (0.01 mol/L) of the polymerization products (2-1b, 2-3b) obtained in Synthesis Example 3 are included instead of the polymerization products (2-2a, 2-4a) obtained in Synthesis Example 1.

### Preparation Example 4

A polishing slurry is prepared in the same manner as in Preparation Example 1, except that 0.235 wt % (0.01 mol/L) of the polymerization products (2-1b, 2-3b) obtained in Synthesis Example 4 are included instead of the polymerization products (2-2a, 2-4a) obtained in Synthesis Example 1.

### Preparation Example 5

A polishing slurry is prepared in the same manner as in Preparation Example 1, except that 0.249 wt % (0.01 mol/L) of the polymerization products (2-2a, 2-4a) obtained in Synthesis Example 5 are included instead of the polymerization products (2-2a, 2-4a) obtained in Synthesis Example 1.

### Preparation Example 6

A polishing slurry is prepared in the same manner as in Preparation Example 1, except that 0.249 wt % (0.01 mol/L) of the polymerization products (2-2a, 2-4a) obtained in Synthesis Example 6 are included instead of the polymerization products (2-2a, 2-4a) obtained in Synthesis Example 1.

### Preparation Example 7

A polishing slurry is prepared in the same manner as in Preparation Example 1, except that 0.242 wt % (0.01 mol/L) of the polymerization products (2-9a, 2-10a) obtained in Synthesis Example 7 are included instead of the polymerization products (2-2a, 2-4a) obtained in Synthesis Example 1.

### Preparation Example 8

A polishing slurry is prepared in the same manner as in Preparation Example 1, except that 0.249 wt % (0.01 mol/L) of the polymerization products (2-2a, 2-4a) obtained in Synthesis Example 8 are included instead of the polymerization products (2-2a, 2-4a) obtained in Synthesis Example 1.

### Comparative Preparation Example 1

A polishing slurry is prepared in the same manner as in Preparation Example 1, except that the polymerization products (2-2a, 2-4a) obtained in Synthesis Example 1 are not included.

### Comparative Preparation Example 2

A polishing slurry is prepared in the same manner as in Preparation Example 1, except that L-histidine (Sigma-Aldrich) represented by Chemical Formula A below is included instead of the polymerization products (2-2a, 2-4a) obtained in Synthesis Example 1:

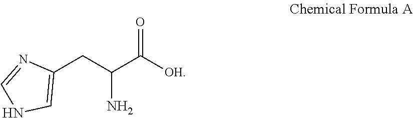 [SMILES: NC(Cc1c[nH]cn1)C(=O)O]

### Evaluation I

The polishing slurries according to Preparation Examples and Comparative Preparation Examples are evaluated with respect to a polishing rate (removal rate, RR) of each Mo layer.

CMP is performed under the following conditions.
(1) CMP equipment: GNP POLI-400L (G&P Technology, Inc.)
(2) Body to be polished: a 40 millimeters (mm)×40 mm silicon wafer coupon with a 5000 Å-thick Mo layer formed by physical vapor deposition (PVD)
(3) Polishing head rotation speed: 87 revolutions per minute (rpm)
(4) Polishing platen rotation speed: 93 rpm
(5) Applied pressure: 3 pounds per square inch (psi)
(6) Initial temperature: 24 °C
(7) Polishing slurry: Polishing Slurries according to the Preparation Examples and Comparative Preparation Examples (25 °C)
(8) Polishing slurry supply flow rate: 130 milliliters per minute (ml/min).
(9) Polishing time: 1 minute

The chemical mechanical polishing rate (removal rate, RR) is calculated according to Calculation Equation 1. In Calculation Equation 1, a thickness of the Mo layer is calculated from sheet resistance and volume resistivity, which are measured using a resistance meter (Model “RS-100”, KLA Tencor) in a DC 4-probe method, according to Calculation Equation 2:

Removal rate (RR, Å/min)=(thickness of Mo layer before polishing (Å)−thickness of Mo layer after polishing (Å))/polishing time (min) Calculation Equation 1

Thickness of Mo layer (Å)=[volume resistivity (Ω·m)+sheet resistance (Ω)]×10¹⁰. Calculation Equation 2

### Evaluation II

The polishing slurries according to Preparation Examples and Comparative Preparation Examples are evaluated with respect to an etching rate (static etching rate, SER) of each Mo layer.

40 mm×40 mm silicon wafers covered with a 5000 Å-thick Mo layer formed by PVD are immersed in each of the polishing slurries (45 °C) according to Preparation Examples and Comparative Preparation Examples for 10 minutes. Subsequently, the silicon wafers are taken out and washed with deionized water. Then, the obtained Mo layers are measured with respect to a thickness before and after the immersion in the same method as above, which is used to calculate the static etching rate (SER, Å/min) according to Calculation Equation 3:

Static etching rate (SER, Å/min)=(Thickness of Mo layer before immersion (Å)−Thickness of Mo layer after immersion (Å))/Immersion time (min). Calculation Equation 3

The results according to Evaluation I and II are shown in Table 1.

TABLE 1

| | | Ratio of Removal Rate to |
|---|---|---|
| | Static Etching Rate | Static Etching Rate |
| | (SER, Å/min) | (RR/SER) |
| Preparation Example 1 | 0.05 | 2020 |
| Preparation Example 2 | 0.1 | 410 |
| Preparation Example 3 | 2 | 50 |
| Preparation Example 4 | 2 | 43.5 |
| Preparation Example 5 | 5 | 59.7 |
| Preparation Example 6 | 2 | 79 |
| Preparation Example 7 | 3 | 62.9 |
| Preparation Example 8 | 2 | 46.8 |
| Comparative Preparation | 84 | 1.8 |
| Example 1 | | |
| Comparative Preparation | 38 | 2.6 |
| Example 2 | | |

Referring to Table 1, it may be confirmed that the polishing slurries according to the Preparation Examples significantly lower the etching rate and significantly increase the ratio of the polishing rate to the etching rate compared to the polishing slurries according to Comparative Preparation Examples. From this, it may be confirmed that corrosion or over-etching of a Mo layer is effectively reduced by the compounds (corrosion inhibitors) obtained in the Synthesis Examples.

While this disclosure has been described in connection with what is presently considered to be practical example embodiments, it is to be understood that the disclosure is not limited to the disclosed embodiments. On the contrary, it is intended to cover various modifications and equivalent arrangements included within the spirit and scope of the appended claims.

What is claimed is:

1. A polishing slurry comprising:
an abrasive,
an oxidizing agent, and
a polymerization product of one or more histidine derivatives, the one or more histidine derivatives comprising a substituted or unsubstituted cyclic imide group, a substituted or unsubstituted amic acid group, or a combination thereof.

2. The polishing slurry of claim 1, wherein the polymerization product of the one or more histidine derivatives comprises a polymerization product of a first histidine derivative comprising a substituted or unsubstituted cyclic imide group, a polymerization product of a second histidine derivative comprising a substituted or unsubstituted amic acid group, a copolymerization product of the first histidine derivative and the second histidine derivative, or a combination thereof.

3. The polishing slurry of claim 2, wherein
the first histidine derivative is represented by Chemical Formula 1-1, and
the second histidine derivative is represented by Chemical Formula 1-2: 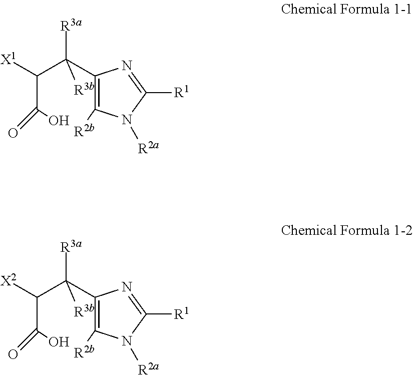
wherein, in Chemical Formula 1-1 and 1-2,
X¹ is a substituted or unsubstituted cyclic imide group having a polymerizable unsaturated bond,
X² is a substituted or unsubstituted amic acid group having a polymerizable unsaturated bond,
R¹, R^{2a}, R^{2b}, R^{3a}, and R^{3b} are each independently hydrogen, deuterium, a substituted or unsubstituted C1 to C20 alkyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} are each independently present or any two adjacent R¹, R^{2a}, R^{2b}, R^{3a}, and R^{3b} are linked to form a ring.

4. The polishing slurry of claim 3, wherein X¹ of Chemical Formula 1-1 is represented by one of Chemical Formulae A to D: 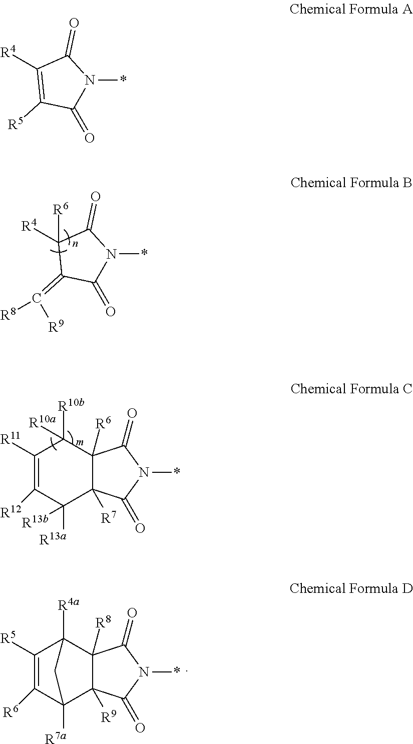
wherein, in Chemical Formulae A to D,
R⁴, R^{4a}, R⁵, R⁶, R⁷, R^{7a}, R⁸, R⁹, R^{10a}, R^{10b}, R¹¹, R¹², R^{13a}, and R^{13b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴, R^{4a}, R⁵, R⁶, R⁷, R^{7a}, R⁸, R⁹, R^{10a}, R^{10b}, R¹¹, R¹², R^{13a}, and R^{13b} are each independently present or any two adjacent R⁴, R^{4a}, R⁵, R⁶, R⁷, R^{7a}, R⁸, R⁹, R^{10a}, R^{10b}, R¹¹, R¹², R^{13a}, and R^{13b} are linked to form a ring,
n is an integer of 1 to 5,
m is an integer of 0 to 5, and
* is a linking point with Chemical Formula 1-1.

5. The polishing slurry of claim 3, wherein X² of Chemical Formula 1-2 is represented by one of Chemical Formulae E to H: 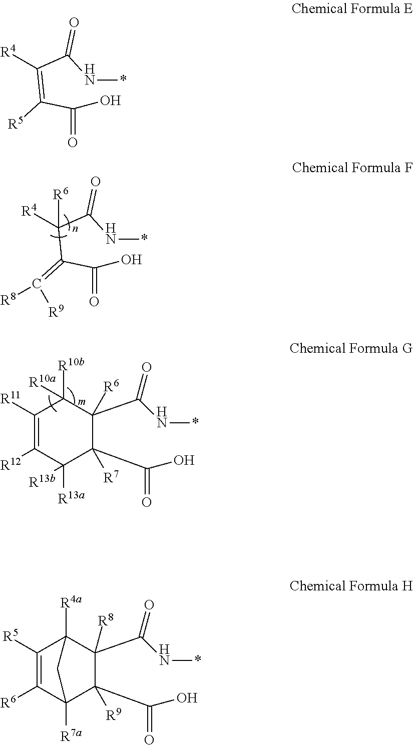
wherein, in Chemical Formulae E to H,
R⁴, R^{4a}, R⁵, R⁶, R⁷, R^{7a}, R⁸, R⁹, R^{10a}, R^{10b}, R¹¹, R¹², R^{13a}, and R^{13b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴, R^{4a}, R⁵, R⁶, R⁷, R^{7a}, R⁸, R⁹, R^{10a}, R^{10b}, R¹¹, R¹², R^{13a}, and R^{13b} are each independently present or any two adjacent R⁴, R^{4a}, R⁵, R⁶, R⁷, R^{7a}, R⁸, R⁹, R^{10a}, R^{10b}, R¹¹, R¹², R^{13a}, and R^{13b} are linked to form a ring,
n is an integer of 1 to 5,
m is an integer of 0 to 5, and
* is a linking point with Chemical Formula 1-2.

6. The polishing slurry of claim 2, wherein
at least some repeating units of the polymerization product of the first histidine derivative comprises a substituted or unsubstituted cyclic imide moiety, a substituted or unsubstituted imidazole moiety, and a carboxyl moiety, and
at least some repeating units of the polymerization product of the second histidine derivative comprises at least one of a substituted or unsubstituted amic acid moiety or a substituted or unsubstituted cyclic imide moiety, a substituted or unsubstituted imidazole moiety, and a carboxyl moiety.

7. The polishing slurry of claim 1, wherein the polymerization product of the histidine derivative comprises at least one of repeating unit represented by one of Chemical Formulae 2-1 to 2-10: 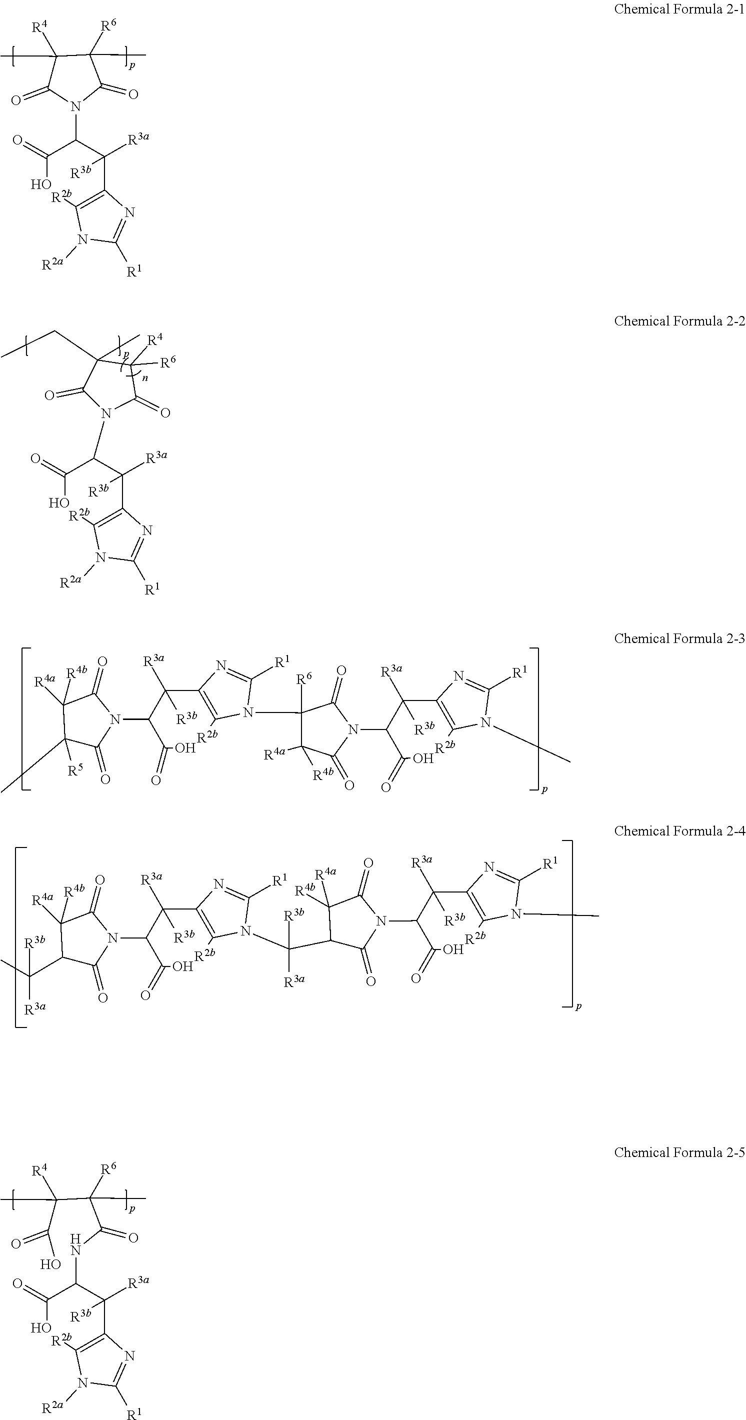 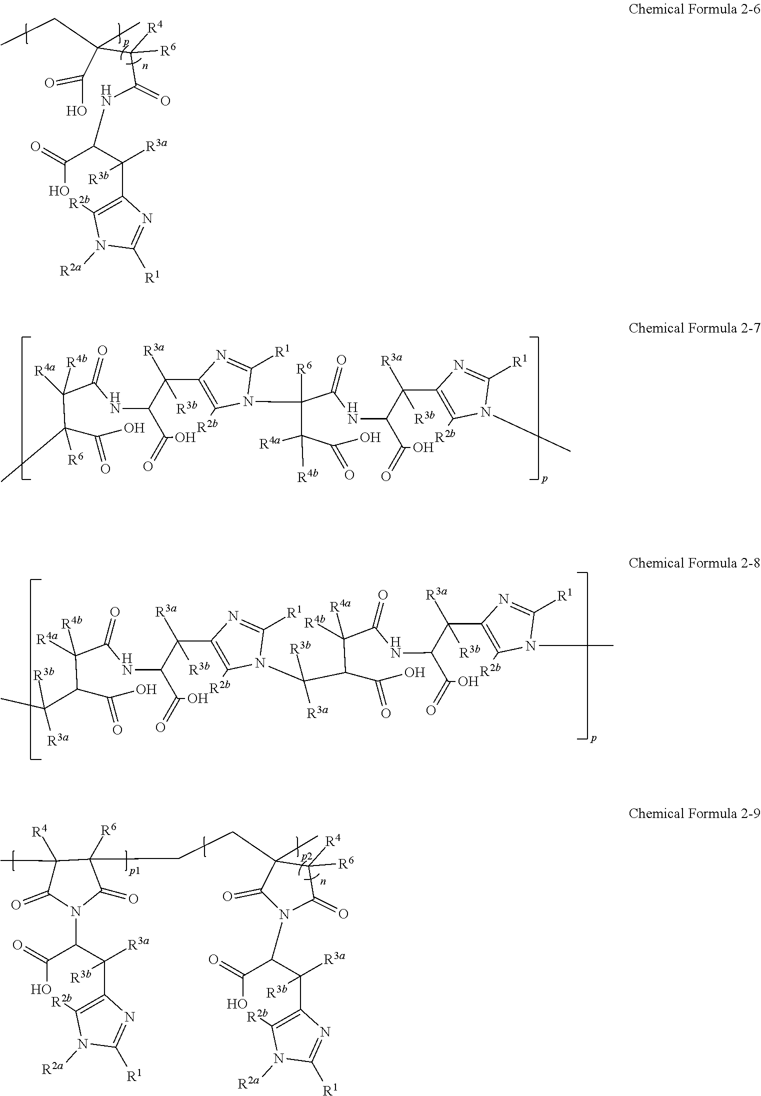 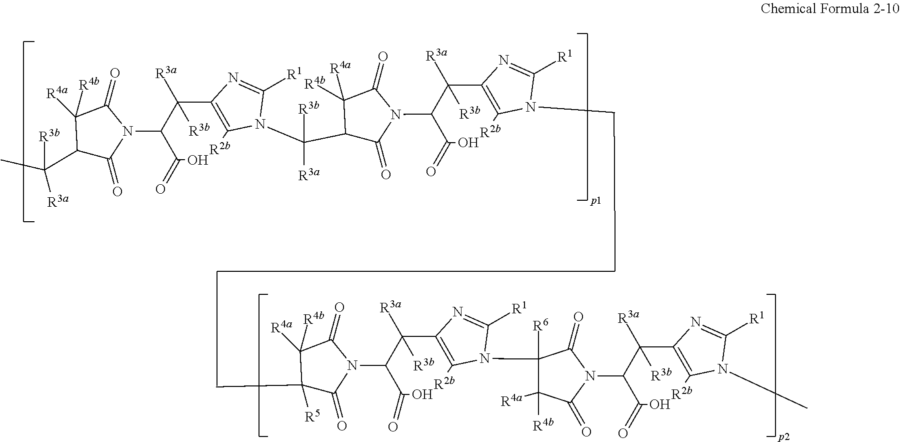
wherein, in Chemical Formulae 2-1 to 2-10,
R¹, R^{2a}, R^{2b}, R^{3a}, R^{3b}, R⁴, R^{4a}, R^{4b}, and R⁶ are each independently hydrogen, deuterium, a substituted or unsubstituted C1 to C20 alkyl group, a substituted or unsubstituted C1 to C20 alkoxy group, a substituted or unsubstituted C6 to C20 aryl group, a carboxyl group, a hydroxy group, a halogen, or a cyano group,
n is an integer of 1 to 5, and
p, p1, and p2 are each independently an integer of 2 to 100.

8. The polishing slurry of claim 1, further comprising a first histidine derivative comprising a substituted or unsubstituted cyclic imide group, a second histidine derivative comprising a substituted or unsubstituted amic acid group, or a combination thereof.

9. The polishing slurry of claim 1, wherein the abrasive comprises an oxide abrasive, a nitride abrasive, a carbon abrasive, or a combination thereof.

10. The polishing slurry of claim 9, wherein the abrasive comprises silica, ceria, alumina, zirconia, titania, silicon nitride, silicon carbide, diamond, fullerene, a derivative thereof, or a combination thereof.

11. The polishing slurry of claim 1, wherein the oxidizing agent comprises hydrogen peroxide, peracetic acid, a percarbonate, urea peroxide, perchloric acid, a persulfate, or a combination thereof.

12. The polishing slurry of claim 1, further comprising a dispersion medium, wherein
the polymerization product of the one or more histidine derivatives and the oxidizing agent are each included in an amount of about 0.001 weight percent to about 5 weight percent, based on a total weight of the polishing slurry, and
the polymerization product of the one or more histidine derivatives and the oxidizing agent are included in a molar ratio of about 0.01:10 to about 10:0.01 in the polishing slurry.

13. The polishing slurry of claim 1, wherein a pH of the polishing slurry is about 1.0 to about 10.0.

14. A method of manufacturing a semiconductor device, the method comprising:
forming a conductive layer on a dielectric layer having a trench or a hole;
supplying a polishing slurry on the conductive layer; and
performing chemical mechanical polishing on the conductive layer to form a conductive pattern embedded in the trench or the hole,
wherein the polishing slurry comprises
an abrasive,
an oxidizing agent, and
a polymerization product of one or more histidine derivatives, the one or more histidine derivatives comprising a substituted or unsubstituted cyclic imide group, a substituted or unsubstituted amic acid group, or a combination thereof.

15. The method of claim 14, wherein the polymerization product of the one or more histidine derivatives comprises a polymerization product of a first histidine derivative comprising a substituted or unsubstituted cyclic imide group, a polymerization product of a second histidine derivative comprising a substituted or unsubstituted amic acid group, a copolymerization product of the first histidine derivative and the second histidine derivative, or a combination thereof.

16. The method of claim 15, wherein
the first histidine derivative is represented by Chemical Formula 1-1, and
the second histidine derivative is represented by Chemical Formula 1-2: 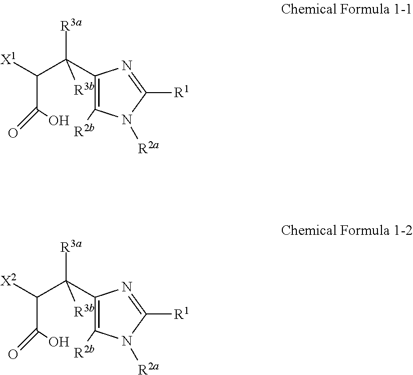
wherein, in Chemical Formula 1-1 or 1-2,
X¹ is a substituted or unsubstituted cyclic imide group having a polymerizable unsaturated bond,
X² is a substituted or unsubstituted amic acid group having a polymerizable unsaturated bond,
R¹, R^{2a}, R^{2b}, R^{3a}, and R^{3b} are each independently hydrogen, deuterium, a substituted or unsubstituted C1 to C20 alkyl group, a substituted or unsubstituted C1 to C20 alkoxy group, a substituted or unsubstituted C6 to C20 aryl group, a carboxyl group, a hydroxy group, a halogen, or a cyano group, and
R¹, R^{2a}, R^{2b}, R^{3a}, and R^{3b} are each independently present or any two adjacent R¹, R^{2a}, R^{2b}, R^{3a}, and R^{3b} are linked to form a ring.

17. The method of claim 16, wherein
X¹ of Chemical Formula 1-1 is represented by one of Chemical Formulae A to D, and
X² of Chemical Formula 1-2 is represented by one of Chemical Formulae E to H: 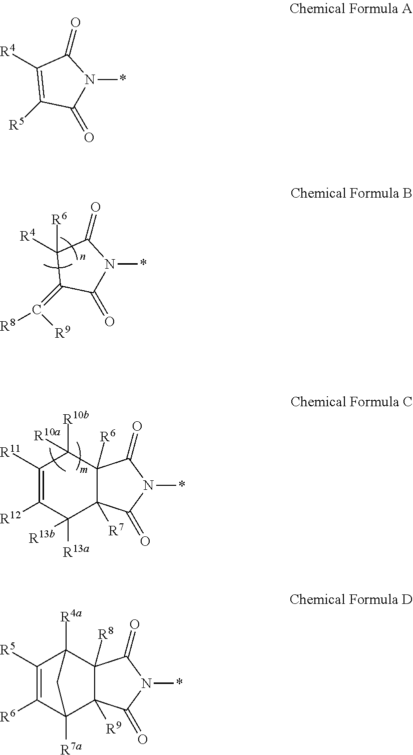 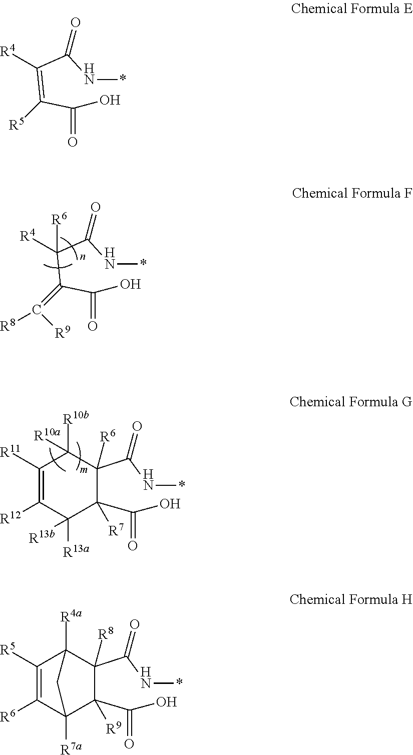
wherein, in Chemical Formulae A to H,
R⁴, R^{4a}, R⁵, R⁶, R⁷, R^{7a}, R⁸, R⁹, R^{10a}, R^{10b}, R¹¹, R¹², R^{13a}, and R^{13b} are each independently hydrogen, deuterium, a substituted or unsubstituted C1 to C20 alkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C20 aryl group, a carboxyl group, a hydroxy group, a halogen, or a cyano group,
R⁴, R^{4a}, R⁵, R⁶, R⁷, R^{7a}, R⁸, R⁹, R^{10a}, R^{10b}, R¹¹, R¹², R^{13a}, and R^{13b} are each independently present or any two adjacent R⁴, R^{4a}, R⁵, R⁶, R⁷, R^{7a}, R⁸, R⁹, R^{10a}, R^{10b}, R¹¹, R¹², R^{13a}, and R^{13b} are linked to form a ring,
n is an integer of 1 to 5,
m is an integer of 0 to 5, and
* is a linking point with Chemical Formula 1-1 or 1-2.

18. The method of claim 15, wherein
at least some repeating units of the polymerization product of the first histidine derivative comprise a substituted or unsubstituted cyclic imide moiety, a substituted or unsubstituted imidazole moiety, and a carboxyl moiety, and
at least some repeating units of the polymerization product of the second histidine derivative comprise at least one of a substituted or unsubstituted amic acid moiety or a substituted or unsubstituted cyclic imide moiety, a substituted or unsubstituted imidazole moiety, and a carboxyl moiety.

19. The method of claim 14, further comprising a first histidine derivative comprising a substituted or unsubstituted cyclic imide group, a second histidine derivative comprising a substituted or unsubstituted amic acid group, or a combination thereof.

20. The method of claim 14, wherein
the conductive layer comprises a molybdenum-containing conductive layer, and
a ratio of a removal rate to a static etching rate of the molybdenum-containing conductive layer is greater than or equal to about 30, wherein the removal rate is determined according to Calculation Equation 1 and the static etching rate is determined according to Calculation Equation 3:
Removal rate (Å/min)=(thickness of Mo layer before polishing (Å)−thickness of Mo layer after polishing (Å))/polishing time (minutes) Calculation Equation 1
Static etching rate (Å/min)=(thickness of Mo layer before immersion (Å)−thickness of Mo layer after immersion (Å))/immersion time (minutes). Calculation Equation 3
